(19) United States
(12) Patent Application Publication
(10) Pub. No.: US 2005/0253195 A1
(43) Pub. Date: Nov. 17, 2005

(54) Semiconductor device and image display device

(75) Inventors: Yoshihiko Toyoda, Hyogo (JP); Takao Sakamoto, Hyogo (JP); Kazuyuki Sugahara, Hyogo (JP); Naoki Nakagawa, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 11/109,818

(22) Filed: Apr. 20, 2005

(30) Foreign Application Priority Data
Apr. 21, 2004 (JP) 2004-125489
Feb. 15, 2005 (JP) 2005-037949

(51) Int. Cl. H01L 21/00

(52) U.S. Cl. 257/347

(57) ABSTRACT

A silicon nitride film and a silicon oxide film are formed on a glass substrate. On the silicon oxide film is formed a thin film transistor including a source region, a drain region, a channel region having a predetermined channel length, a GOLD region and an LDD region having an impurity concentration lower than the impurity concentration of the source region, a GOLD region and an LDD region having an impurity concentration lower than the impurity concentration of the drain region, a gate insulation film, and a gate electrode. The gate electrode is formed overlapping with and facing the channel region and the GOLD region. A semiconductor device is obtained, directed to improving source-drain breakdown voltage and AC stress resistance, and achieving desired current property.

### BACKGROUND OF THE INVENTION

1. Field of the Invention

The present invention relates to a semiconductor device and an image display device. More particularly, the present invention relates to a semiconductor device applied to display devices such as a liquid crystal display device and organic EL (Electro Luminescence) display device, and an image display device including an image display circuit unit.

2. Description of the Background Art

A thin film transistor is used in a display device. As an example of such a thin film transistor, a thin film transistor of a GOLD (Gate Overlapped Lightly Doped Drain) structure disclosed in Japanese Patent Laying-Open No. 2002-076351 will be described hereinafter. An n type thin film transistor of a GOLD structure has a source region, a drain region, a channel region, a GOLD region, a gate insulation film, a gate electrode and the like formed on a glass substrate.

At a region between the channel region and the drain region, the GOLD region is formed particularly at a region located right under the gate electrode, overlapping with the gate electrode in plane. The GOLD region has an impurity concentration higher than that of the channel region, and lower than that of the drain region.

The operation of an n type, for example, thin film transistor of such a GOLD structure will be described here. By applying a predetermined positive voltage to the gate, a channel is formed at the channel region. The resistance between the source region and the drain region is reduced, allowing a current flow across the source region and the drain region.

In contrast, when a negative voltage is applied to the gate, the resistance between the source region and the drain region becomes larger since a channel is not formed at the channel region. Substantial current cannot be conducted across the source region and the drain region, and only a small leakage current will flow.

This leakage current is caused by the recoupling, at the junction, between holes formed at the channel and many electrons located at the source region and drain region. Since the probability of recoupling is increased when the electric field at the junction becomes higher, leakage current will be increased.

In a display device, the voltage applied to the liquid crystal must be maintained for the duration of one frame until the screen is rewritten. If leakage current at the pixel transistor employed for retaining the voltage is great, the voltage applied to the liquid crystal will be decreased over time to degrade the display property. It is therefore necessary to minimize the leakage current in a pixel transistor.

As another example of a thin film transistor employed in a display device, a thin film transistor of an LDD (Lightly Doped Drain) structure disclosed in Japanese Patent Laying-Open No. 2001-345448 will be described hereinafter. An n type thin film transistor of an LDD structure has a source region, a drain region, a channel region, an LDD region, a gate insulation film, a gate electrode and the like formed on a glass substrate.

The LDD region is formed at a region between the channel region and drain region. The LDD region is set to have an impurity concentration higher than that of the channel region and lower than that of the drain region.

In a thin film transistor of an LDD structure, application of a negative voltage as the gate voltage will cause an accumulation layer to be formed at the channel region. The electric field in the proximity of the source and drain is alleviated by the LDD region to suppress the leakage current.

Conventional thin film transistors have problems set forth below. As mentioned above, a thin film transistor employed as a pixel transistor must have the leakage current suppressed to an extremely low level. In a thin film transistor of a GOLD structure that is one example of a thin film transistor, application of a negative voltage as the gate voltage will result in the formation of an accumulation layer at the GOLD region, whereby a high electric field is generated in the proximity of the source region and drain region having an impurity concentration higher than that of the GOLD region. Therefore, leakage current could not be suppressed, adversely affecting the characteristic of the OFF current in the thin film transistor.

Furthermore application of a voltage to the drain higher than that to the gate will generate a relatively large electric field at the junction region of the drain side. Electrons accelerated by this electric field induce impact ionization, whereby a pair of an electron and hole is generated. Impact ionization is repeated to increase the pairs of electrons and holes, causing increase in the drain current to result in avalanche breakdown. The drain voltage at this stage becomes the source-drain breakdown voltage.

Since the electric field in the proximity of the drain region is alleviated at the junction between the channel region and GOLD region in the thin film transistor of a GOLD structure set forth above, impact ionization can be suppressed to a certain level. However, there was a problem that sufficient source-drain breakdown voltage could not be achieved by the length of practical usage of the GOLD region (GOLD length).

Additionally, degradation in the property of the thin film transistor is observed when a positive and negative AC (Alternating Current) pulse is applied to the gate. This reliability with respect to such AC stress is specific to a thin film transistor employing polycrystalline. Specifically, application of a negative voltage to the gate will cause a large electric field at the junction between the gate and the source/drain, and the carriers captured at the grain boundary of the polycrystals are gradually released. These carriers are accelerated by the intensive electric field at the junction to induce impact ionization.

Since the pair of electron and hole generated by impact ionization has an extremely high energy, it may exceed the energy barrier between the gate oxide film and the semiconductor to enter the oxide film. Such pairs of electrons and holes having high energy are referred to as “hot carriers”. and are introduced into the oxide film to form fixed charge, or cause defect at the boundary to degrade the mobility. Thus, the characteristics of the transistor will be degraded.

A thin film transistor of a conventional GOLD structure can have generation of hot carriers suppressed to some level since the electric field in the proximity of the drain region is alleviated at the junction between the channel region and the GOLD region. However, there was a problem that the reliability with respect to AC stress is low and sufficient hot carrier resistance cannot be achieved with the GOLD length of practical usage.

Thin film transistors of the another example have a similar problem. Although impact ionization can be suppressed to some level since the electric field in the proximity of the drain region is alleviated at the junction between the channel region and LDD region, sufficient source/drain breakdown voltage and/or sufficient reliability with respect to AC stress could not be achieved with the length of practical usage of the LDD region (LDD length).

When a channel is formed at the channel region by applying a positive voltage as the gate voltage, the resistor of the LDD region will be connected in series with the channel resistor. Since the impurity concentration of the LDD region is lower than the impurity concentration of the source region and drain region, the resistance at the LDD region will become higher to lead to the problem that the ON current becomes lower.

Thus, sufficient source/drain breakdown voltage and AC stress resistance could not be achieved by conventional thin film transistors. Furthermore, there was a problem that the desired OFF current property or ON current property (current property) could not be achieved.

### SUMMARY OF THE INVENTION

In view of the foregoing, an object of the present invention is to provide a semiconductor device directed to improving the source-drain breakdown voltage and AC stress resistance, achieving desired current property.

Another object of the present invention is to provide an image display device including an image display circuit unit with such a semiconductor device.

According to an aspect of the present invention, a semiconductor device includes a semiconductor element having a semiconductor layer, an insulation film, and an electrode formed on a predetermined substrate. The semiconductor element includes a first element. The first element includes a first impurity region, a second impurity region, a channel region, a third impurity region, a fourth impurity region, a fifth impurity region, and a sixth impurity region. The first impurity region is formed at the semiconductor layer. The second impurity region is formed at the semiconductor layer with a distance from the first impurity region. The channel region is formed at a region of the semiconductor layer between the first impurity region and the second impurity region with respective distances from the first and second impurity regions. The channel region has a predetermined channel length. The third impurity region is formed in contact with the channel region, at a region of the semiconductor layer between the first impurity region and the channel region. The fourth impurity region is formed in contact with the channel region, at a region of the semiconductor layer between the second impurity region and the channel region. The fifth impurity region is formed at a region of the semiconductor layer between the first impurity region and the third impurity region. The sixth impurity region is formed at a region of the semiconductor layer between the second impurity region and the fourth impurity region. In the first element, the electrode has one side and another side opposite to each other. A junction between the third impurity region and the fifth impurity region is located substantially on the same plane as the one side. A junction between the fourth impurity region and the sixth impurity region is located substantially on the same plane as the another side. The electrode is formed overlapping with and facing the channel region, the third impurity region, and the fourth impurity region entirely. The insulation film is formed between the semiconductor layer and electrode so as to come into contact with each of the semiconductor layer and electrode. The impurity concentration of each of the third to sixth impurity regions is set lower than the impurity concentration of each of the first and second impurity regions, and higher than the impurity concentration of the channel region. The impurity concentration of the third and fourth impurity regions is set to be different from the impurity concentration of the fifth and sixth impurity regions.

In accordance with the structure set forth above, the third and fourth impurity regions (GOLD region) having an impurity concentration higher than that of the channel region and lower than that of the first impurity region (source) and second impurity region (drain) are formed at a region located between the channel region and the first impurity region, and at a region located between the channel region and the second impurity region, facing the electrode. Additionally, the fifth and sixth impurity regions (LDD structure) having an impurity concentration lower than that of the first and second impurity regions and higher than that of the channel region are formed at a region located between the first impurity region and the third impurity region, and at a region located between the second impurity region and the fourth impurity region. Therefore, higher source-drain breakdown voltage and AC stress resistance can be achieved, as compared to an element of a conventional LDD structure. Furthermore, a low OFF current property can be achieved.

An image display device of the present invention includes an image display circuit unit to display an image. The image display circuit unit includes a semiconductor element having a semiconductor layer, an insulation film, and an electrode formed on a predetermined substrate. The semiconductor element includes a first element and a second element. The first element includes a first impurity region, a second impurity region, a channel region, a third impurity region, a fourth impurity region, a fifth impurity region, and a sixth impurity region. The second element includes a seventh impurity region, an eighth impurity region, a ninth impurity region, and a tenth impurity region. The first element has the first impurity region formed at the semiconductor layer. The second impurity region is formed at the semiconductor layer with a distance from the first impurity region. The channel region is formed at a region of the semiconductor layer between the first impurity region and the second impurity region, with respective distances from the first impurity region and the second impurity region. The channel region has a predetermined channel length. The third impurity region is formed in contact with the channel region at a region of the semiconductor layer between the first impurity region and the channel region. The fourth impurity region is formed in contact with the channel region at a region of the semiconductor layer between the second impurity region and the channel region. The fifth impurity region is formed at a region of the semiconductor layer between the first impurity region and the third impurity region. The sixth impurity region is formed at a region of the semiconductor layer between the second impurity region and the fourth impurity region. The electrode has one side and another side opposite to each other. A junction between the third impurity region and the fifth impurity region is located substantially on the same plane as the one side. The junction between the fourth impurity region and the sixth impurity region is located substantially on the same plane as the another side. The electrode is formed overlapping with and facing the channel region, the third impurity region, and the fourth impurity region entirely. The insulation film is formed between the semiconductor layer and the electrode so as to come into contact with each of the semiconductor layer and the electrode. The impurity concentration of the third to sixth impurity regions is set lower than the impurity concentration of the first and second impurity regions, and higher than the impurity concentration of the channel region. The impurity concentration of the third and fourth impurity regions is set different from the impurity concentration of the fifth and sixth impurity regions. The second element has the seventh impurity region formed at the semiconductor layer. The eighth impurity region is formed at the semiconductor layer with a distance from the seventh impurity region. The channel region is formed at a region of the semiconductor layer between the seventh impurity region and the eighth impurity region with respective distances from the seventh impurity region and the eighth impurity region. The channel region has a predetermined channel length. The ninth impurity region is formed in contact with the channel region at a region of the semiconductor layer between the seventh impurity region and the channel region. The tenth impurity region is formed in contact with the channel region at a region of the semiconductor layer between the eighth impurity region and the channel region. The electrode has one side and another side opposite to each other. The junction between the channel region and the ninth impurity region is located substantially on the same plane as the one side. The junction between the channel region and the tenth impurity region is located substantially on the same plane as the another side. The electrode is formed overlapping with and facing the channel region entirely. The insulation film is formed between the semiconductor layer and the electrode so as to come into contact with the semiconductor layer and the electrode. The impurity concentration of each of the ninth impurity region and the tenth impurity region is set lower than the impurity concentration of each of the seventh impurity region and the eighth impurity region, and higher than the impurity concentration of the channel region.

In accordance with the structure set forth above, higher source-drain breakdown voltage and AC stress resistance can be achieved by the first element. Also, low OFF current property can be achieved. Additionally, by employing a second element having a smaller occupying area than the first element, increase of the area occupied by the image display circuit unit can be suppressed as compared to the case where only the first element is employed.

A fabrication method of the semiconductor device of the present invention includes the steps of forming a first electrode on a substrate having a main surface, forming a predetermined first semiconductor layer on the substrate, forming an insulation film on the substrate between the step of forming an electrode and the step of forming a semiconductor layer; forming on the first semiconductor layer a first mask material including a first portion so as to cross the first semiconductor layer; introducing impurity ions of a predetermined conductivity type into the first semiconductor layer using the first mask material as a mask to form a pair of first impurity regions having a predetermined impurity concentration at a portion of the semiconductor layer located at one region and another region with the mask material therebetween so as to come into contact with a channel region, a portion of the first semiconductor layer located right under the mask material being the channel region (first implantation step); forming on the first semiconductor layer a second mask material including a first portion covering the channel region entirely and respective portions of the first impurity regions constituting a pair; introducing impurity ions of a predetermined conductivity type into the first semiconductor layer using the second mask material as a mask to form a pair of second impurity regions having an impurity concentration higher than the impurity concentration of the first impurity region at a portion of the first semiconductor layer located at one side and another side with the channel region therebetween, with respective distances from the channel region (second implantation step); forming on the first semiconductor layer a third mask material including the first portion, covering the channel region entirely and respective portions of the first impurity regions constituting a pair; and introducing impurity ions of a predetermined conductivity type into the first semiconductor layer using the third mask material as a mask to form a pair of third impurity regions with respective distances shorter than the predetermined distance from the channel region, at a portion of the first semiconductor layer located at one side and another side with the channel therebetween (third implantation step). In the step of forming a first electrode and the step of forming a first impurity region, the first electrode is formed so as to overlap with and face the channel region and the first impurity regions constituting a pair entirely.

In accordance with the fabrication method, the pair of first impurity regions corresponding to the GOLD region is formed by the first implantation step using the first mask material as a mask. Therefore, a semiconductor device with a GOLD region can be readily produced by just adding one mask material. Furthermore, modification of the length and the like of the first impurity region in the direction of the channel length can be readily accommodated by adjusting the dimension of the first mask material.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device according to a first embodiment of the present invention.

FIG. 2 is a sectional view of the semiconductor device of the first embodiment, representing a step in a method of fabricating the semiconductor device of FIG. 1.

FIG. 3 is a sectional view of the semiconductor device of the first embodiment, representing a step carried out after the step of FIG. 2.

FIG. 4 is a sectional view of a semiconductor device of the first embodiment, representing a step carried out after the step of FIG. 3.

FIG. 5 is a sectional view of a semiconductor device of the first embodiment, representing a step carried out after the step of FIG. 4.

FIG. 6 is a sectional view of a semiconductor device of the first embodiment, representing a step carried out after the step of FIG. 5.

FIG. 7 is a sectional view of a semiconductor device of the first embodiment, representing a step carried out after the step of FIG. 6.

FIG. 8 is a sectional view of a semiconductor device of the first embodiment, representing a step carried out after the step of FIG. 7.

FIG. 9 is a sectional view of a semiconductor device of the first embodiment, representing a step carried out after the step of FIG. 8.

FIG. 10 represents the results of source-drain breakdown voltage of thin film transistors according to the first embodiment.

FIG. 11 represents the results of ON current of thin film transistors according to the first embodiment.

FIG. 12 represents the results of OFF current in thin film transistors according to the first embodiment.

FIG. 13 represents the results of AC stress resistance in thin film transistors according to the first embodiment.

FIG. 14 represents the comparison of the etching process between the thin film transistor of a GOLD structure according to the present invention and a thin film transistor of a conventional GOLD structure.

FIG. 15 is a sectional view of a semiconductor device according to a second embodiment of the present invention, representing a step of a fabrication method thereof.

FIG. 16 is a sectional view of the semiconductor device according to the second embodiment of the present invention, representing a step carried out after the step of FIG. 15.

FIG. 17 is a sectional view of the semiconductor device according to the second embodiment of the present invention, representing a step carried out after the step of FIG. 16.

FIG. 18 is a sectional view of the semiconductor device according to the second embodiment of the present invention, representing a step carried out after the step of FIG. 17.

FIG. 19 is a sectional view of the semiconductor device according to the second embodiment of the present invention, representing a step carried out after the step of FIG. 18.

FIG. 20 is a sectional view of the semiconductor device according to the second embodiment of the present invention, representing a step carried out after the step of FIG. 19.

FIG. 21 represents the results of source-drain breakdown voltage of thin film transistors according to the second embodiment.

FIG. 22 represents the results of ON current of thin film transistors according to the second embodiment.

FIG. 23 represents the results of OFF current in thin film transistors according to the second embodiment.

FIG. 24 represents the results of AC stress resistance in thin film transistors according to the second embodiment.

FIG. 25 is a sectional view of a semiconductor device according to a third embodiment of the present invention, representing a step of a fabrication method thereof.

FIG. 26 is a sectional view of the semiconductor device of the third embodiment, representing a step carried out after the step of FIG. 25.

FIG. 27 is a sectional view of the semiconductor device of the third embodiment, representing a step carried out after the step of FIG. 26.

FIG. 28 is a sectional view of a semiconductor device according to the third embodiment of the present invention, representing a step carried out after the step of FIG. 27.

FIG. 29 is a sectional view of the semiconductor device according to the third embodiment, representing a step carried out after the step of FIG. 28.

FIG. 30 is a graph representing the dependency of saturation degradation rate on the impurity concentration of the GOLD region in a fourth embodiment of the present invention.

FIG. 31 is a graph representing the dependency of saturation degradation rate on the GOLD length in a fifth embodiment of the present invention.

FIG. 32 is a graph representing the dependency of AC stress lifetime on the LDD length in a sixth embodiment of the present invention.

FIG. 33 is a graph representing the dependency of ON current on the difference between the LDD length at the source side and the LDD length at the drain side in a seventh embodiment of the present invention.

FIG. 34 is a sectional view of a semiconductor device according to an eighth embodiment, representing a step of a fabrication method thereof.

FIG. 35 is a sectional view of the semiconductor device of the eighth embodiment, representing a step carried out after the step of FIG. 34.

FIG. 36 is a sectional view of the semiconductor device of the eighth embodiment, representing a step carried out after the step of FIG. 35.

FIG. 37 is a sectional view of the semiconductor device of the eighth embodiment, representing a step carried out after the step of FIG. 36.

FIG. 38 is a sectional view of the semiconductor device of the eighth embodiment, representing a step carried out after the step of FIG. 37.

FIG. 39 represents the results of source-drain breakdown voltage of thin film transistors according to the eighth embodiment.

FIG. 40 represents the results of ON current of thin film transistors according to the eighth embodiment.

FIG. 41 represents the results of OFF current of thin film transistors according to the eighth embodiment.

FIG. 42 is a graph representing the dependency of source-drain breakdown voltage on the impurity concentration of the GOLD region in a ninth embodiment of the present invention.

FIG. 43 is a graph representing the dependency of AC stress lifetime on the impurity concentration of the GOLD region in the ninth embodiment.

FIG. 44 is a graph representing the dependency of source-drain breakdown voltage on the impurity concentration of the LDD region in a tenth embodiment of the present invention.

FIG. 45 is a graph representing the dependency of AC stress lifetime on the impurity concentration of the LDD region in the tenth embodiment.

FIG. 46 is a graph representing the dependency of OFF current on the impurity concentration of the LDD region in the tenth embodiment.

FIG. 47 is a graph representing the dependency of source-drain breakdown voltage on the GOLD length in an eleventh embodiment of the present invention.

FIG. 48 is a graph representing the dependency of AC stress lifetime on the GOLD length in the eleventh embodiment.

FIG. 49 is a graph representing the dependency of source-drain breakdown voltage on the LDD length according to a twelfth embodiment of the present invention.

FIG. 50 is a graph representing the dependency of AC stress lifetime on the LDD length according to the twelfth embodiment.

FIG. 51 is a graph representing the dependency of OFF current on the LDD length according to the twelfth embodiment.

FIG. 52 is a graph representing the dependency of ON current on the LDD length in the twelfth embodiment.

FIG. 53 is a sectional view of a semiconductor device according to a thirteenth embodiment of the present invention, representing a step in a fabrication method thereof.

FIG. 54 is a sectional view of the semiconductor device of the thirteenth embodiment, representing a step carried out after the step of FIG. 53.

FIG. 55 is a sectional view of the semiconductor device of the thirteenth embodiment, representing a step carried out after the step of FIG. 54.

FIG. 56 is a graph representing the dependency of ON current on the difference between the LDD length at the source side and the LDD length at the drain side in the thirteenth embodiment.

FIG. 57 is a graph representing the dependency of OFF current on the difference between the LDD length in the thirteenth embodiment.

FIG. 58 is a plan view of a semiconductor device according to a fourteenth embodiment of the present invention.

FIG. 59 is a sectional view of the semiconductor device of the fourteenth embodiment, taken along line LIX-LIX of FIG. 58.

FIG. 60 represents the measured results of OFF current according to the fourteenth embodiment.

FIG. 61 is a sectional view of a semiconductor device according to a fifteenth embodiment of the present invention, representing a step in a fabrication method thereof.

FIG. 62 is a sectional view of the semiconductor device of the fifteenth embodiment, representing a step carried out after the step of FIG. 61.

FIG. 63 is a sectional view of the semiconductor device of the fifteenth embodiment, representing a step carried out after the step of FIG. 62.

FIG. 64 is a sectional view of the semiconductor device of the fifteenth embodiment, representing a step carried out after the step of FIG. 63.

FIG. 65 is a sectional view of the semiconductor device of the fifteenth embodiment, representing a step carried out after the step of FIG. 64.

FIG. 66 is a sectional view of the semiconductor device of the fifteenth embodiment, representing a step carried out after the step of FIG. 65.

FIG. 67 is a sectional view of the semiconductor device of the fifteenth embodiment, representing a step carried out after the step of FIG. 66.

FIG. 68 is a sectional view of a semiconductor device according to a sixteenth embodiment of the present invention, representing a step in a fabrication method thereof.

FIG. 69 is a sectional view of the semiconductor device of the sixteenth embodiment, representing a step carried out after the step of FIG. 68.

FIG. 70 is a sectional view of the semiconductor device of the sixteenth embodiment, representing a step carried out after the step of FIG. 69.

FIG. 71 is a sectional view of the semiconductor device of the sixteenth embodiment, representing a step carried out after the step of FIG. 70.

FIG. 72 is a sectional view of the semiconductor device of the sixteenth embodiment, representing a step carried out after the step of FIG. 71.

FIG. 73 is a sectional view of the semiconductor device of the sixteenth embodiment, representing a step carried out after the step of FIG. 72.

FIG. 74 is a sectional view of the semiconductor device of the sixteenth embodiment, representing a step carried out after the step of FIG. 73.

FIG. 75 is a sectional view of the semiconductor device of the sixteenth embodiment, representing a step carried out after the step of FIG. 74.

FIG. 76 is a block diagram of a configuration of a liquid crystal display device according to a seventeenth embodiment of the present invention.

FIG. 77 is a graph representing the dependency of occupying area ratio of the thin film transistor of a GOLD structure of the present invention to the thin film transistor of a conventional LDD structure on the gate length in the seventeenth embodiment.

FIG. 78 is a block diagram of a configuration of a liquid crystal display device according to an eighteenth embodiment of the present invention.

FIG. 79 is a block diagram of a configuration of a liquid crystal display device according to a nineteenth embodiment of the present invention.

FIG. 80 is a block diagram of a configuration of a liquid crystal display device according to a twentieth embodiment of the present invention.

FIG. 81 is a graph representing the dependency of occupying area ratio of the thin film transistor of a GOLD structure of the present invention to the thin film transistor of a conventional LDD structure on the number of gate electrodes according to the twentieth embodiment.

### DESCRIPTION OF THE PREFERRED EMBODIMENTS

### First Embodiment

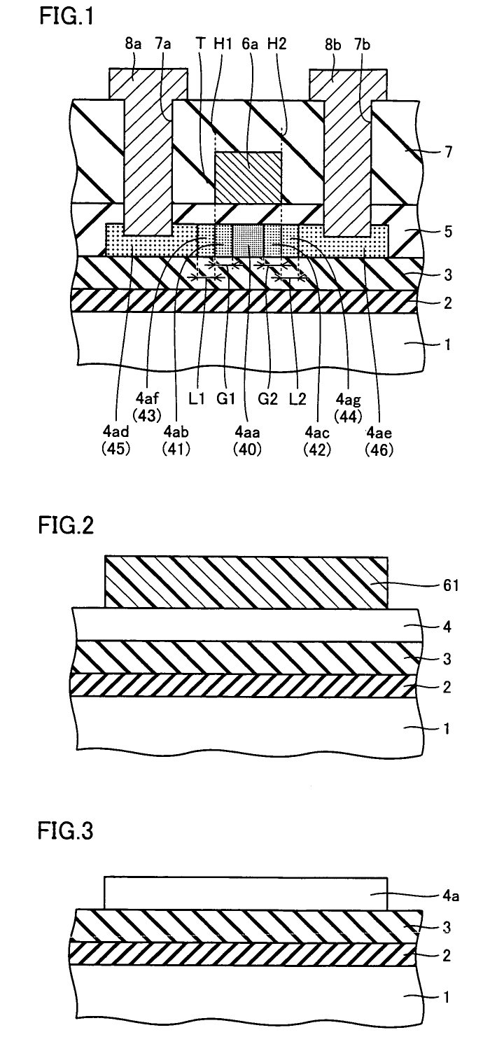

A semiconductor device according to a first embodiment of the present invention will be described hereinafter. Referring to FIG. 1, a silicon nitride film 2 is formed on a glass substrate 1. A silicon oxide film 3 is formed on silicon nitride film 2. An island-shaped polycrystalline silicon film is formed on silicon oxide film 3. At the polycrystalline silicon film are formed a source region 45 having a predetermined impurity concentration, and a drain region 46 spaced apart from source region 45, and having a predetermined concentration.

At the region located between source region 45 and drain region 46, a channel region 40 having a predetermined channel length is formed with respective distances from source region 45 and drain region 46.

At the region between source region 45 and channel region 40, an LDD region 43 is formed at the side of source region 45, and a GOLD region 41 is formed at the side of channel region 40. Furthermore, at the region located between drain region 46 and channel region 40, an LDD region 44 is formed at the side of source region 46, and a GOLD region 42 is formed at the side of channel region 40.

The impurity concentration of each of LDD regions 43 and 44 and GOLD regions 41 and 42 is set higher than that of channel region 40, and lower than that of source region 45 and drain region 46. Furthermore, the impurity concentration of LDD regions 43 and 44 is set higher than that of GOLD regions 41 and 42.

A gate insulation film 5 formed of a silicon oxide film is deposited so as to cover the island-shaped polycrystalline silicon film. A gate electrode 6a is formed on gate insulation film 5. An interlayer insulation film 7 formed of a silicon oxide film, for example, is deposited so as to cover gate electrode 6a.

A contact hole 7a and a contact hole 7b exposing the surface of source region 45 and drain region 46, respectively, are formed in interlayer insulation film 7. A source electrode 8a and a drain electrode 8b are formed on interlayer insulation film 7 so as to fill contact holes 7a and 7b, respectively.

A thin film transistor T is implemented including gate electrode 6a, source region 45, drain region 46, LDD regions 43 and 44, GOLD regions 41 and 42, and channel region 40: In particular, gate electrode 6a is formed to cover the entirety of channel region 40, and overlapping with GOLD regions 41 and 42 in plane.

In other words, the junction between one GOLD region 41 and LDD region 43 is located substantially on the same plane H1 as one side of gate electrode 6a, whereas the junction between the other GOLD region 42. and LDD region 44 is located substantially on the same plane H2 as the other side of gate electrode 6a.

An example of a fabrication method of the semiconductor device set forth above will be described here. Referring to FIG. 2, silicon nitride film 2 of approximately 100 nm in film thickness is deposited by plasma CVD (Chemical Vapor Deposition), for example, on the main surface of a glass substrate 1 of Type 1737 made by Corning Inc. Silicon oxide film 3 is formed to a thickness of approximately 100 nm on silicon nitride film 2. Then, an amorphous silicon film 4 of approximately 50 nm in film thickness is formed on silicon oxide film 3.

Silicon nitride film 2 is provided to prevent the impurities included in glass substrate 1 from diffusing upwards. As a film to prevent such impurity diffusion, the material of SiON, SiC, AlN, Al₂O₃, and the like may be applied in addition to the silicon nitride film. Although a double-layer structure of silicon nitride film 2 and silicon oxide film 3 is provided as the underlying film of amorphous silicon film 4, the present invention is not limited to such a double-layer structure. Such films may be omitted, or another film may be additionally layered.

By subjecting amorphous silicon film 4 to heat treatment in predetermined vacuum, hydrogen, present in amorphous silicon film 4 and that is not required, is removed. Then, amorphous silicon film 4 is irradiated with a laser beam by XeCl laser, for example, to be rendered polycrystalline, resulting in a polycrystalline silicon film 4, as shown in FIG. 2. Polycrystalline silicon film 4 has a grain size of approximately 0.5 μm.

Additionally, YAG laser, CW laser, or the like can be used instead of the XeCl laser. Furthermore, the amorphous silicon film may be rendered polycrystalline by thermal annealing. In the event of applying thermal annealing, polycrystalline silicon of a larger grain size can be obtained by using a catalyst such as nickel. A resist pattern 61 is formed on polycrystalline silicon film 4.

As shown in FIG. 3, polycrystalline silicon film 4 is subjected to anisotropic etching with resist pattern 61 as a mask, resulting in an island-shaped polycrystalline silicon film 4a. Then, ashing and chemical treatment are applied to remove resist pattern 61.

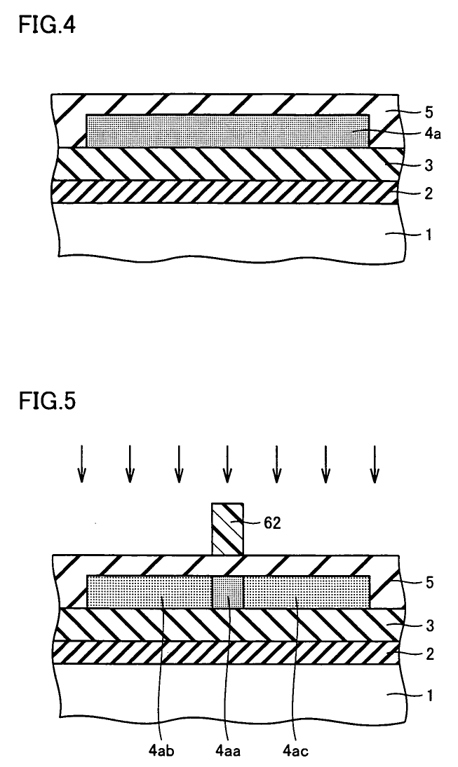

Referring to FIG. 4, a gate insulation film 5 formed of a silicon oxide film is deposited by plasma CVD, for example, to a thickness of approximately 100 nm so as to cover polycrystalline silicon film 4a. In this case, liquid TEOS (Tetra Ethyl Ortho Silicate) is employed as the base material of the silicon oxide film.

To control the threshold value of the thin film transistor, boron is implanted into polycrystalline silicon film 4a with a dosage of 1×10¹² atom/cm² and acceleration energy of 60 KeV, for example. This implantation process is to be carried out as necessary, and may be omitted.

Referring to FIG. 5, predetermined photolithography is applied to form a resist pattern 62. Then, phosphorus is implanted into polycrystalline silicon film 4a with a dosage of 5×10¹² atom/cm² and acceleration energy of 80 KeV, for example, using resist pattern 62 as a mask, to obtain impurity regions 4ab and 4ac.

The implanted amount thereof corresponds to the amount of implantation (impurity concentration) of the GOLD region. An impurity region 4aa functioning as a channel is formed between impurity regions 4ab and 4ac. Then, ashing and chemical treatment are applied to remove resist pattern 62.

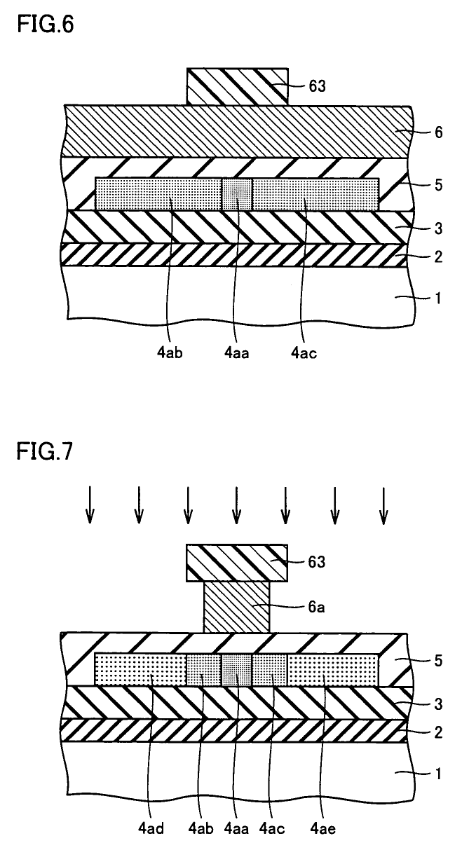

Referring to FIG. 6, a chromium film 6 of approximately 400 nm in film thickness is formed all over gate insulation film 5 by sputtering. Then, predetermined photolithography is applied to form a resist pattern 63.

Chromium film 6 is subjected to wet etching using resist pattern 63 as a mask, whereby a gate electrode 6a is obtained as shown in FIG. 7. Gate electrode 6a is formed so as to overlap in plane with impurity regions 4ab and 4ac located with impurity region 4aa therebetween. The region overlapping with gate electrode 6a in plane in impurity regions 4ab and 4ac becomes the GOLD region.

In the wet etching step, the side surface of exposed chromium film 6 is etched. The etched amount thereof can be controlled by the period of time of overetching.

Using resist pattern 63 as a mask, phosphorus is implanted into impurity regions 4ab and 4ac with a dosage of 1×10¹⁴ atom/cm², and acceleration energy of 80 KeV, for example, to form impurity regions 4ad and 4ae identified as the source region and drain region. Then, ashing and chemical treatment are applied to remove resist pattern 63.

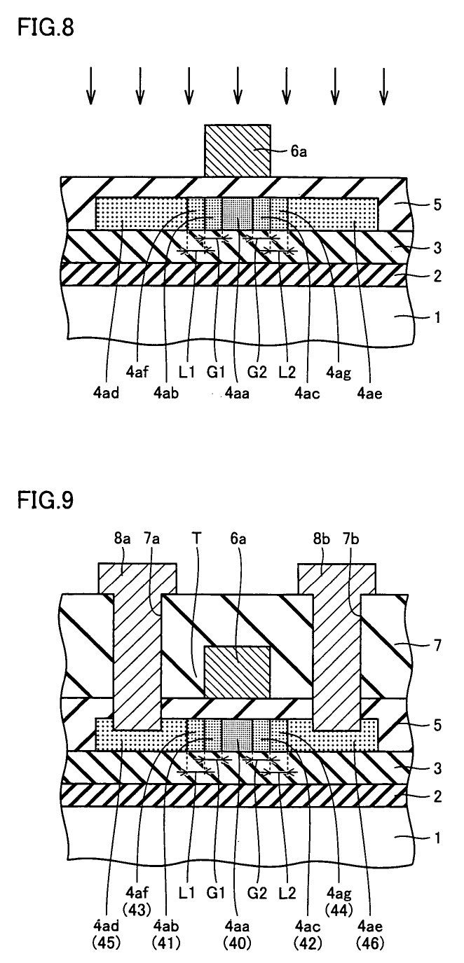

Referring to FIG. 8, using gate electrode 6a as a mask, phosphorus is implanted with the dosage of 1×10¹³ atom/cm² and acceleration energy of 80 KeV, for example, to form impurity regions 4af and 4ag identified as the LDD region at remaining impurity regions 4ab and 4ac. The impurity concentration of impurity regions 4af and 4ag identified as the LDD region is determined by the implanted amount of phosphorus thereto and the amount of phosphorus implanted for the formation of the GOLD region.

Thus, by the formation of impurity regions 4af and 4ag, the impurity concentration of impurity regions 4ab and 4ac identified as the GOLD region becomes lower than the impurity concentration of impurity regions 4af and 4ag identified as the LDD region.

Referring to FIG. 9, an interlayer insulation film 7 formed of a silicon oxide film is deposited to a thickness of approximately 400 nm by plasma CVD, for example, so as to cover gate electrode 6a. Predetermined photolithography is applied on interlayer insulation film 7, whereby a resist pattern (not shown) required to form a contact hole is provided. Interlayer insulation film 7 and gate insulation film 5 are subjected to anisotropic etching using the resist pattern as a mask, whereby a contact hole 7a exposing the surface of impurity region 4ad and a contact hole 7b exposing the surface of impurity region 4ae are formed.

A multilayer film of a chromium film and aluminum film (not shown) is formed on interlayer insulation film 7 so as to fill contact holes 7a and 7b. Predetermined photolithography is applied on the multilayer film, whereby a resist pattern (not shown) required to form an electrode is provided. Wet etching is applied using this resist pattern as a mask to obtain a source electrode 8a and a drain electrode 8b.

Thus, the main part of a semiconductor device including a thin film transistor T is formed. In this thin film transistor T, impurity region 4ad and impurity region 4ae are identified as source region 45 and drain region, respectively, impurity regions 4af and 4ag are identified as LDD regions 43 and 44, respectively, impurity regions 4ab and 4ac are identified as GOLD regions 41 and 42, respectively, and impurity region 4aa is identified as channel region 40.

LDD regions 43 and 44 have a predetermined length L1 and a predetermined length L2, respectively, in the direction of the channel length. GOLD regions 41 and 42 have a predetermined length G1 and a predetermined length G2, respectively, in the direction of the channel length. The LDD lengths L1 and L2 of LDD regions 43 and 44 are set substantially the same. The GOLD lengths G1 and G2 of GOLD regions 41 and 42 are set substantially the same.

Measurements of the source-drain breakdown voltage of thin film transistor T set forth above will be described hereinafter. For the measurement, a thin film transistor of the following parameters was employed: gate width 10 μm; effective gate length 5 μm; length of GOLD regions 41 and 42 in direction of channel length 1 μm; length of LDD regions 43 and 44 in direction of channel length 0.5 μm; and length of gate electrode 6a in direction of channel length 7 μm.

For comparison, measurement was also conducted using a thin film transistor of a conventional LDD structure and a thin film transistor of a conventional GOLD structure. The thin film transistor of a conventional LDD structure had the following parameters: gate width 10 μm; gate length 5 μm; and length of LDD region in direction of channel length 0.5 μm. The thin film transistor of a conventional GOLD structure had the following parameters: gate width 10 μm; gate length 5 μm; length of GOLD region in direction of channel length 1 μm; and length of gate electrode in direction of channel length 7 μm.

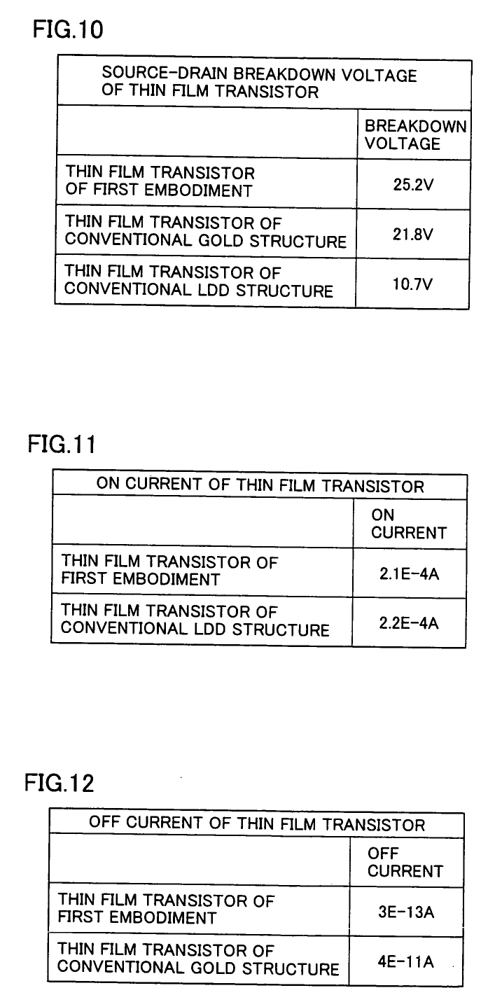

The measured results of source-drain breakdown voltage are shown in FIG. 10. In the measurement, the gate voltage was set to 0V, and the source was connected to ground. The source-drain breakdown voltage is defined as the drain voltage when the drain current is 0.1 μA. As shown in FIG. 10, it is appreciated that the thin film transistor of a GOLD structure of the first embodiment exhibits a higher source-drain breakdown voltage as compared to a thin film transistor of a conventional GOLD structure and a thin film transistor of a conventional LDD structure.

The measured results of ON current will be described hereinafter. In the measurement, the source was connected to ground, and 5V and 5V were applied to the gate and drain, respectively. The drain current measured under such conditions is taken as the ON current. The measured results of such ON current is shown in FIG. 11. As shown in FIG. 11, it is appreciated that the thin film transistor of a GOLD structure of the first embodiment exhibits ON current substantially equal to the ON current of a thin film transistor of a conventional LDD structure having the same length for the LDD regions.

The measured results of OFF current will be described here. In the measurement, the source was connected to ground, and 5V and −5V were applied to the drain and gate, respectively. The drain current measured under such conditions is taken as the OFF current. The measured results of such OFF current is shown in FIG. 12. As shown in FIG. 12, it is appreciated that the thin film transistor of a GOLD structure of the first embodiment provides an OFF current lower than the OFF current of a thin film transistor of a conventional GOLD structure.

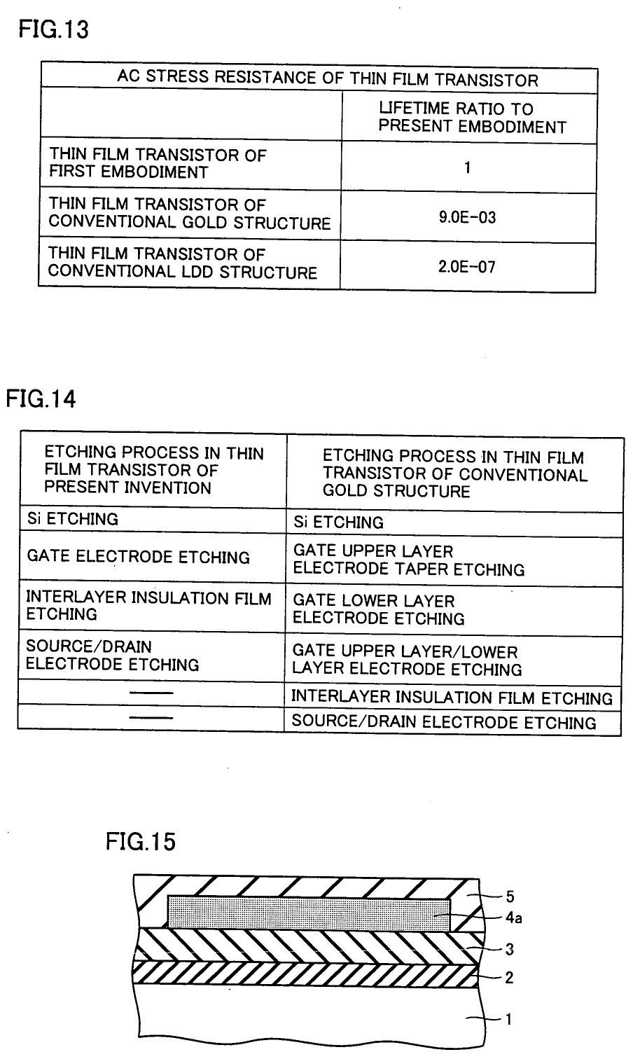

The results of evaluating the AC stress lifetime will be described here. With regards to the AC stress conditions, the gate voltage, source voltage, and drain voltage were set to ±15V, 0V, and 0V, respectively. The stress time period for the ON current to become 80% is taken as the AC stress lifetime. The results of the AC stress lifetime are shown in FIG. 13.

Each AC stress lifetime is represented by the relative value (ratio) with the AC stress lifetime of the thin film transistor of the first embodiment as 1. As shown in FIG. 13, it is appreciated that the AC stress lifetime of the thin film transistor of the first embodiment is increased significantly, as compared to that of the thin film transistor of a conventional GOLD structure and the thin film transistor of the conventional LDD structure. It was identified that the reliability with respect to AC stress can be improved.

Evaluation of the implanted amount of impurities (impurity concentration) in the GOLD region and LDD region in a thin film transistor produced according to the fabrication method set forth above will be described here. A specimen for evaluation was produced in a manner similar to that of forming a thin film transistor. Specifically, a silicon nitride film of approximately 100 nm in film thickness, a silicon oxide film of approximately 100 nm in film thickness, and an amorphous silicon film of approximately 50 nm in film thickness are sequentially formed on a glass substrate, followed by a predetermined laser annealing process on the amorphous silicon film.

Then, a silicon oxide film of approximately 100 nm in film thickness is formed, followed by ion implantation of phosphorus directed to forming a GOLD region and ion implantation of phosphorus directed to forming an LDD region. The amount of impurities implanted was measured by SIMS (Secondary Ion Mass Spectrometer). It was identified that the amount of impurities corresponding to the GOLD region was 5×10¹⁷ atom/cm³, and the amount of impurities corresponding to the LDD region was 1.5×10¹⁸ atom/cm³.

The GOLD region is formed by the impurity ions implanted using resist pattern 62 formed on gate insulation film 5 as a mask. There is known a conventional method of forming a GOLD region by employing a double layered structure for the gate electrode, and implanting impurity ions via the tapered lower layer portion using the upper layer portion as a mask.

This method is disadvantageous in that, in the etching step to form the upper layer portion of the gate electrode, the lower layer portion is also etched away, resulting in an uneven thickness for the lower layer portion. The implanted amount in the step of implanting impurity ions via the lower layer portion may vary greatly. Furthermore, it is necessary to set the implantation energy higher since impurity ions are implanted via a metal material that constitutes the gate electrode, which will lead to further variation in the implanted amount of impurity ions.

In contrast, the fabrication method set forth above of the first embodiment has the impurity ions for the formation of a GOLD region implanted immediately after the gate insulation film is formed. Therefore, the impurity ion implantation amount is affected only by variation in the thickness of the gate insulation film. Thus, variation in the implanted amount of impurity ions can be suppressed more than in the conventional case.

In the conventional method, the length of the GOLD region in the direction of the channel length (GOLD length) is controlled by the taper angle during the formation of the upper layer electrode through etching. If the taper angle is small, the GOLD length will vary greatly depending upon variation in the taper angle and etching rate. Therefore, the conventional method was disadvantageous in that control of the dimension of the GOLD length is difficult. There is also a problem that the GOLD length is restricted if the taper angle is reduced.

In order to form the gate electrode in a tapered configuration, the etching reaction with respect to the portion to be etched and the deposition reaction of the product must proceed with balance in the dry etching apparatus. There was a problem that control of the etching process is extremely difficult.

In contrast, the method set forth above of the first embodiment has impurity ions for formation of the GOLD region implanted using the resist pattern as a mask. Therefore, the GOLD length can be set arbitrarily. There is an advantage that controllability of the dimension of the GOLD length is increased.

Thus, the fabrication method of a thin film transistor of the present embodiment has impurity ions for formation of a GOLD region implanted using the resist pattern as a mask, after the gate insulation film is formed, so that controllability of the implanted amount as well as controllability of the GOLD length is high. The degree of freedom with respect to the process of the GOLD length can be improved.

By employing a single layer structure for the gate electrode in the thin film transistor set forth above, the number of etching processes including the etching step to form a gate electrode can be reduced, as compared to the conventional case. This is shown in FIG. 14. It is appreciated that 4 etching steps are required for the completion of a thin film transistor according to the present embodiment. In contrast, 6 etching steps are required for the completion of a thin film transistor according to the conventional method.

It is to be noted that particles (foreign objects) are readily generated in the etching process, which will become the cause of degrading the yield. By reducing the number of times of etching steps carried out, the yield can be improved and the cost reduced.

### Second Embodiment

The second embodiment is directed to an example in which the impurity concentration of the GOLD region is higher than the impurity concentration of the LDD region. First, a fabrication method according to the second embodiment will be described. The process up to the step of forming gate insulation film 5 as shown in FIG. 15 and implanting predetermined impurities to control the threshold value of the thin film transistor is similar to the process up to the step of FIG. 4 set forth before.

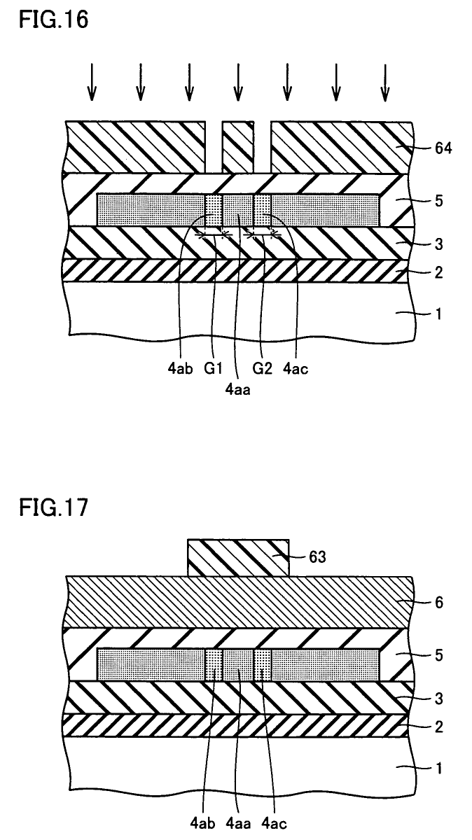

Referring to FIG. 16, predetermined photolithography is applied to form a resist pattern 64. Using resist pattern 64 as a mask, phosphorus is implanted with a dosage of 1×10¹³ atom/cm² and acceleration energy of 80 KeV, for example, to obtain impurity regions 4ab and 4ac that will be the GOLD region. The implanted amount thereof corresponds to the amount of implantation of the GOLD region. Then, ashing and chemical treatment are applied to remove resist pattern 64.

Referring to FIG. 17, chromium film 6 of approximately 400 nm in thickness is formed all over gate insulation film 5 by sputtering. Predetermined photolithography is applied on chromium film 6 to form resist pattern 63. Resist pattern 63 is formed so as to overlap with impurity regions 4ab and 4ac. The portion of impurity regions 4ab and 4ac overlapping with resist pattern 63 is the GOLD region.

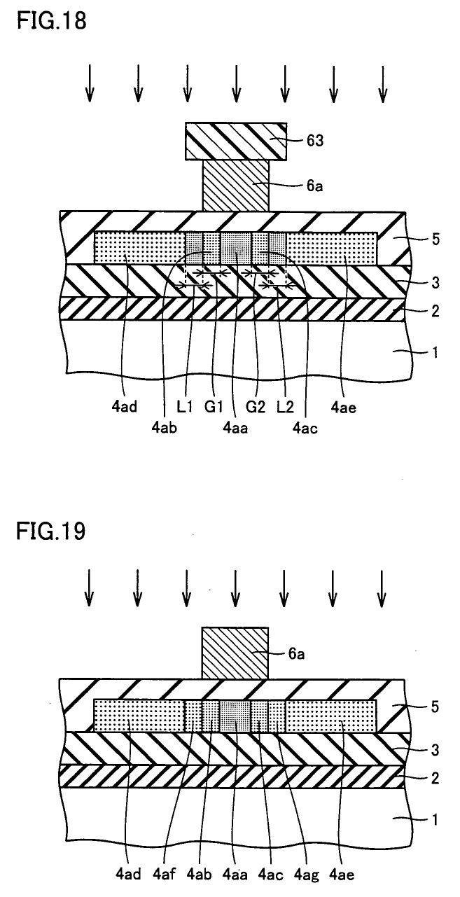

Referring to FIG. 18, chromium film 6 is subjected to wet etching using resist pattern 63 as a mask to obtain gate electrode 6a. During wet etching, the side surface of exposed chromium film 6 is etched away. The etched amount thereof is controlled by the period of time of overetching.

Using resist pattern 63 as a mask, phosphorus is implanted with a dosage of 1×10¹⁴ atom/cm² and acceleration energy of 80 KeV, for example, to obtain impurity regions 4ad and 4ae, identified as the source region and drain region, respectively. Then, ashing and chemical treatment are applied to remove resist pattern 63.

Referring to FIG. 19, phosphorus is implanted with a dosage of 5×10¹² atom/cm² and acceleration energy of 80 KeV, for example, using gate electrode 6a as a mask, to obtain impurity regions 4af and 4ag identified as the LDD region. The implanted amount thereof corresponds to the amount of implantation of the LDD region. In this case, the impurity concentration of the GOLD region is set higher than that of the LDD region and lower than that of the source region and the drain region.

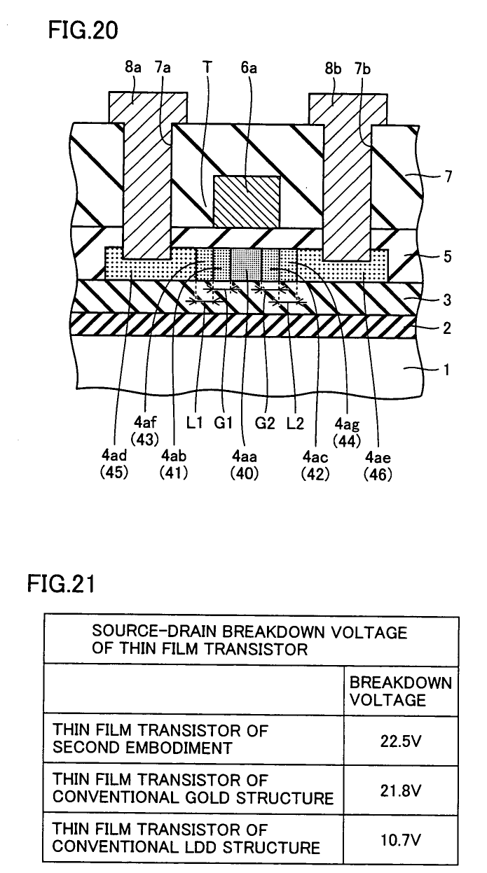

Then, a step similar to the step of FIG. 9 set forth above is carried out to obtain an n channel type thin film transistor of a GOLD structure, as shown in FIG. 20.

Measurements of the source-drain breakdown voltage of the thin film transistor set forth above will be described hereinafter. For the measurement, a thin film transistor of the following parameters was employed: gate width 10 μm; gate length 5 μm; length of GOLD regions 41 and 42 in direction of channel length 1 μm; length of LDD regions 43 and 44 in direction of channel length 0.5 μm; and length of gate electrode 6a in direction of channel length 7 μm.

For comparison, measurement was conducted using a thin film transistor of a conventional LDD structure and a thin film transistor of a conventional GOLD structure. The thin film transistor of a conventional LDD structure had the following parameters: gate width 10 μm; gate length 5 μm; and length of LDD region in direction of channel length 0.5 μm. The thin film transistor of a conventional GOLD structure had the following parameters: gate width 10 μm; gate length 5 μm; length of GOLD region in direction of channel length 1 μm; and length of gate electrode in direction of channel length 7 μm.

The measured results of source-drain breakdown voltage are shown in FIG. 21. The measurement conditions are similar to those set forth before. As shown in FIG. 21, it is appreciated that the thin film transistor of a GOLD structure of the second embodiment exhibits a higher source-drain breakdown voltage, as compared to a thin film transistor of a conventional GOLD structure and a thin film transistor of a conventional LDD structure.

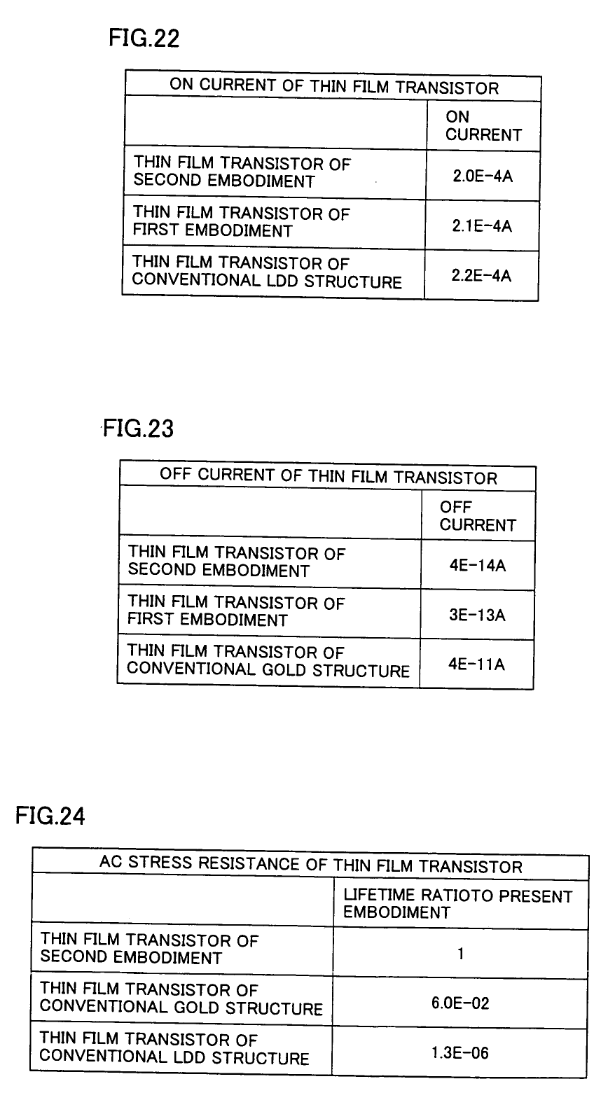

The measured results of ON current will be described hereinafter. The measurement conditions are similar to those set forth before. The measured results of such ON current are shown in FIG. 22. As shown in FIG. 22, it is appreciated that the thin film transistor of a GOLD structure of the second embodiment exhibits an ON current substantially equal to the ON current of a thin film transistor of a conventional LDD structure having the same length for the LDD regions.

The measured results of OFF current will be described here. The measurement conditions are similar to those set forth before. The measured results of such OFF current are shown in FIG. 23. As shown in FIG. 23, it is appreciated that the thin film transistor of a GOLD structure of the second embodiment provides an OFF current lower than the OFF current of a thin film transistor of a conventional GOLD structure and a thin film transistor of the first embodiment.

The results of evaluating the AC stress lifetime will be described here. The measurement conditions are similar to those set forth before. The results of the AC stress lifetime are shown in FIG. 24. As shown in FIG. 24, it is appreciated that the AC stress lifetime of the thin film transistor of the second embodiment is increased significantly, as compared to that of a thin film transistor of a conventional GOLD structure and the thin film transistor of a conventional LDD structure. It was identified that reliability with respect to AC stress can be improved.

The impurity implantation amount (impurity concentration) of the GOLD region and LDD region in a thin film transistor produced in accordance with the fabrication method set forth above was measured through a method similar to that described above. The amount of impurities corresponding to the GOLD region was 1×10¹⁸ atom/cm³, whereas the amount of impurities with respect to the LDD region was 5×10¹⁷ atom/cm³.

### Third Embodiment

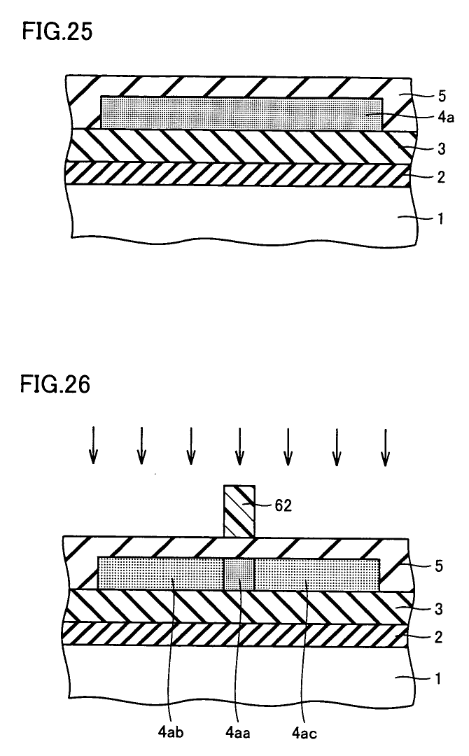

The third embodiment is directed to another example of a fabrication method of a thin film transistor, differing from the fabrication method described in the second embodiment. The process up to the step of forming gate insulation film 5 as shown in FIG. 25 and implanting predetermined impurities to control the threshold value of the thin film transistor is similar to the process up to the step of FIG. 4 set forth before.

Referring to FIG. 26, predetermined photolithography is applied to form resist pattern 62 on gate insulation film 5. Using resist pattern 62 as a mask, phosphorus is implanted with a dosage of 1×10¹³ atom/cm² and acceleration energy of 80 KeV, for example, to obtain impurity regions 4ab and 4ac that will be the GOLD region. The implanted amount thereof corresponds to the amount of implantation of the GOLD region. Then, ashing and chemical treatment are applied to remove resist pattern 62.

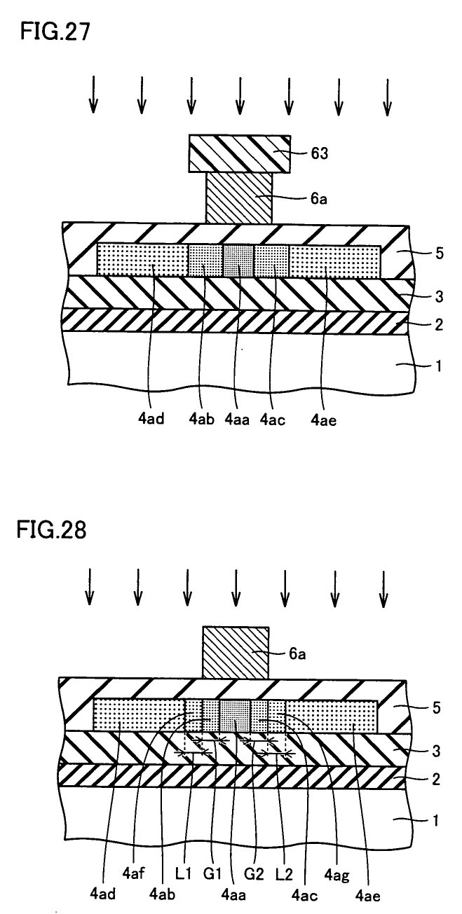

Then, the process similar to that corresponding to the steps shown in FIGS. 6 and 7 set forth before is carried out to obtain resist pattern 63 and gate electrode 63a. Referring to FIG. 27, phosphorus is implanted with a dosage of 1×10¹⁴ atom/cm² and acceleration energy of 80 KeV, for example, using resist pattern 63 as a mask to obtain impurity regions 4ad and 4ae identified as a source region and drain region, respectively. Then, ashing and chemical treatment are applied to remove resist pattern 63.

Referring to FIG. 28, boron is implanted with a dosage of 4×10¹² atom/cm² and acceleration energy of 60 KeV, for example, using gate electrode 6a as a mask to obtain impurity regions 4af and 4ag identified as the LDD region.

In the region where p type boron is implanted in the phosphorus-implanted n type impurity regions 4ab and 4ac, the carrier concentration is reduced by the implantation of p type impurities (boron), whereby the effective impurity concentration is reduced. Accordingly, the impurity concentration of impurity regions 4af and 4ag identified as the LDD region becomes lower than the impurity concentration of impurity regions 4ab and 4ac identified as the GOLD region.

In other words, the effective impurity concentration of the LDD region is determined by the difference between the implanted amount of ion for the formation of the LDD region and the implanted amount of ion for the formation of the GOLD region. Therefore, the impurity concentration of the GOLD region becomes higher than that of the LDD region and lower than that of the source region and drain region.

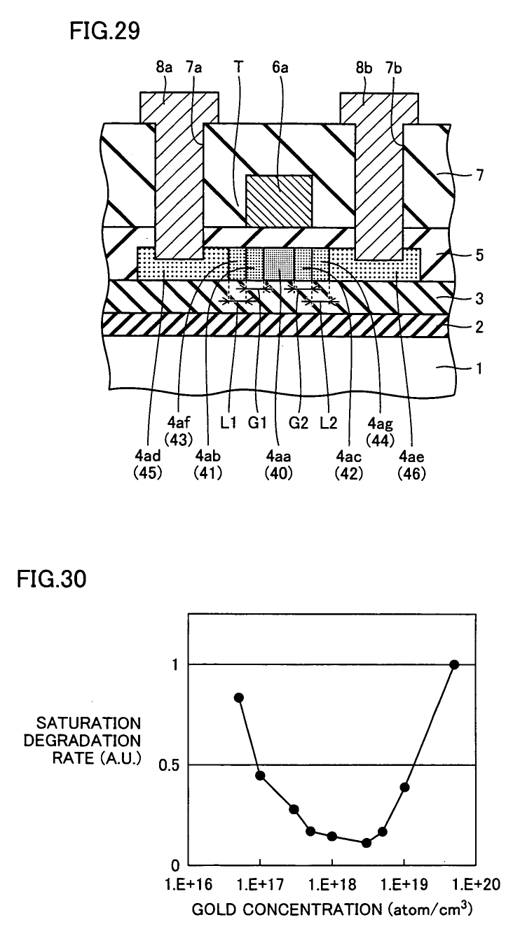

Then, a step similar to the step of FIG. 9 set forth above is carried out to obtain an n channel type thin film transistor of a GOLD structure, as shown in FIG. 29. It was identified that the thin film transistor fabricated in accordance with the third embodiment can achieve the same properties as those of the thin film transistor of the second embodiment.

In a semiconductor device having the impurity concentration of the GOLD region set higher than the impurity concentration of the LDD region as described above, the electric field in the proximity of the drain is alleviated by the junction between the channel region and GOLD region, and the LDD region having an impurity concentration lower than that of the GOLD region, so that sufficient source-drain breakdown voltage and AC stress resistance can be achieved. Although the degradation rate when stress is applied depends upon the stress time period and increases in proportion to a longer stress time period, the progress of degradation is saturated at a certain value of the degradation rate. The inventors found that degradation is saturated at a certain degradation rate where degradation is low by further increasing the impurity concentration of the GOLD region. In this context, the transistor property can be set stable over a long period of time. Furthermore. since the GOLD region overlaps with the gate electrode and a channel is also formed in the GOLD region during the channel formation step, the GOLD region will not adversely affect the ON current. When the channel is OFF, the electric field in the proximity of the source and drain is alleviated by the LDD region to allow a lower OFF current.

The degradation rate and saturation degradation rate are defined as set forth below. First, AC stress is applied on a thin film transistor, whereby the ON current is reduced. “Degradation rate” refers to this rate of degradation of ON current. The degradation rate (ΔI/I_{O}) is obtained by ΔI/I_{O}=(I_{O}−I)/I_{O}, where ΔI is the degraded amount of ON current (degradation amount), I_{O}, is the initial value of current, and I is the ON current after applying AC stress. As the duration of applying AC stress on the thin film. transistor becomes longer, the progress of degradation (reduction in ON current) is saturated. “Saturation degradation rate” is defined as the degradation rate when the degradation rate is saturated. In the present specification, degradation rate is used in the meaning of the degradation rate of ON current for a certain stress time period. The saturation degradation rate is also the degradation rate when the ON current is saturated with respect to the stress time period. This value is unique to the semiconductor device. In the respective evaluation results that will be described afterwards, the dependency of this saturation degradation rate on the impurity concentration of the GOLD region and the GOLD length is indicated.

The range of the impurity concentration in the GOLD region, the length of the GOLD region in the direction of the channel length, the length of the LDD region in the direction of the channel length, and the difference in the length between the LDD regions at the source side and drain side in the direction of the channel length for semiconductor devices in which the impurity concentration of the GOLD region is higher than that of the LDD region will be described in detail in the fourth to seventh embodiments hereinafter.

### Fourth Embodiment

The impurity concentration of the GOLD region in a thin film transistor will be described in the fourth embodiment. To obtain a range of the impurity concentration, thin film transistors having different impurity concentrations in the GOLD region were produced and the electrical property thereof was evaluated. Thin film transistors were produced according to a fabrication method similar to that described in the second embodiment. Specifically, the gate width is 10 μm, the gate length is 5 μm, the length of the GOLD region in the direction of the channel length is 1 μm, the length of the LDD region in the direction of the channel length is 0.5 μm, the length of the gate electrode in the direction of the channel length is 7 μm, and the impurity concentration of the LDD region is half the impurity concentration of the GOLD region in the produced thin film transistors.

FIG. 30 is a graph representing the dependency of saturation degradation rate on the impurity concentration in the GOLD region when AC stress is applied. As shown in FIG. 30, it is appreciated that the saturation degradation amount can be suppressed by setting the impurity concentration of the GOLD region to at least 1×10¹⁷ atom/cm³ and not more than 1×10¹⁹ atom/cm³. It is appreciated that the saturation degradation amount can be suppressed when the impurity concentration of the GOLD region is particularly in the range of at least 5×10¹⁷ atom/cm³ and not more than 5×10¹⁸ atom/cm³.

### Fifth Embodiment

In the fifth embodiment, the length of the GOLD region in the direction of the channel length in a thin film transistor will be described. To obtain a range of the length of the GOLD region in the direction of the channel length (GOLD length), various thin film transistors with different GOLD lengths were fabricated, and the electrical property thereof was evaluated.

The thin film transistors were produced according to the fabrication method similar to that described in the first embodiment to have the following parameters: gate width 10 μm; gate length 5 μm; and length of LDD region in direction of channel length 0.5 μm. The length of the gate electrode in the direction of the channel length was varied in accordance with the length of the GOLD region in the direction of the channel length. The impurity concentration of the GOLD region was set to 1×10¹⁸ atom/cm³. The impurity concentration of the LDD region was set to 5×10¹⁷ atom/cm³.

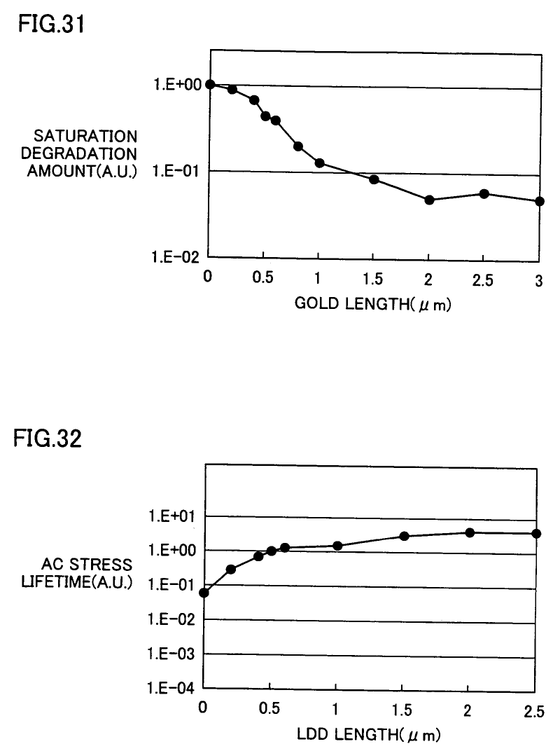

FIG. 31 is a graph representing the dependency of the saturation degradation rate on the length of the GOLD region in the direction of the channel length when AC stress is applied. It is appreciated from FIG. 31 that the saturation degradation rate is reduced when the GOLD length becomes shorter than 0.5 μm to suppress the saturation degradation amount. Although a longer GOLD length is desirable since the saturation degradation amount is apt to become smaller as the GOLD length becomes longer, the saturation degradation rate is apt to be saturated if the GOLD length exceeds 2 μm. Furthermore, increase in the GOLD length will lead to a larger transistor. It is therefore desirable to set the GOLD length to not more than 2 μm. Thus, from the standpoint of saturation degradation and the area occupied by the transistor, the GOLD length is preferably set to at least 0.5 μm and not more than 2 μm.

### Sixth Embodiment

The length of the LDD region in the direction of the channel length in a thin film transistor will be described in the present embodiment. To obtain a range of the length of the LDD region in the direction of the channel length (LDD length), various thin film transistors with different LDD lengths were produced, and the electric property thereof was evaluated.

The thin film transistors were produced according to a fabrication method similar to that described in the first embodiment to have the following parameters: gate width 10 μm; gate length 5 μm; length of GOLD region in direction of channel length 1 μm; and length of gate electrode in direction of channel length 7 μm. The impurity concentration of the GOLD region was set to 1×10¹⁸ atom/cm³. The impurity concentration of the LDD region was set to 5×10¹⁷ atom/cm³.

FIG. 32 is a graph representing the dependency of AC stress lifetime on the length of the LDD region in the direction of the channel length (LDD length). It is appreciated from FIG. 32 that the AC stress lifetime is apt to become shorter when the LDD length is below 0.5 μm. It is also appreciated that there is no great change in the AC stress lifetime when the LDD length exceeds 1.5 μm and is apt to become saturated. The ON current will become lower as the LDD length becomes longer. It is desirable to set the LDD length to not more than 1.5 μm. Thus, from the standpoint of AC stress lifetime and ON current, the LDD length is preferably set to at least 0.5 μm and not more than 1.5 μm.

### Seventh Embodiment

The difference in length in the direction of the channel length between the LDD region at the source side and the LDD region at the drain side in a thin film transistor will be described in the present embodiment. Difference in the length in the direction of the channel length between the LDD region at the source side and the LDD region at the drain side affects the ON current.

In the case where a predetermined voltage is applied to the gate and drain and the source is connected to ground, the voltage drop by the LDD region at the source side causes the voltage across the gate and source to become lower than the voltage applied to the gate. Since this voltage drop is due to the resistance of the LDD region at the source side, the drain current will also be reduced if the LDD length at the source side is longer in the direction of the channel length than the LDD length at the drain side. Therefore, it is preferable that the difference between the LDD length at the source side and the LDD length at the drain side is small.

In order to obtain a range of the difference between the source side LDD length and drain side LDD length, various thin film transistors were produced having different source side LDD lengths based on a constant sum of the source side LDD length and the drain side LDD length, and the electrical property thereof was evaluated.

The thin film transistors employed in the evaluation had the following parameters: gate width 10 μm; gate length 5 μm; length of GOLD region in direction of channel length 1 μm; and length of gate electrode in direction of channel length 7 μm. The impurity concentration of the GOLD region was set to 1×10¹⁸ atom/cm³. The impurity concentration of the LDD region was set to 5×10¹⁷ atom/cm³.

In the previous fabrication method of a semiconductor device described in the second embodiment, impurity regions 4ad and 4ae identified as the source and drain regions were formed by implanting ions using the resist pattern required for the formation of a gate electrode as a mask (refer to FIG. 18). In the present embodiment, the thin film transistors are produced as set forth below. After the gate electrode is formed, the resist pattern is removed, and a resist pattern for the formation of source and drain regions is provided. Using that resist pattern as a mask, ions are implanted to form source and drain regions. Then, the resist pattern is removed, and ions are implanted to the entire surface of the semiconductor substrate to form the LDD region.

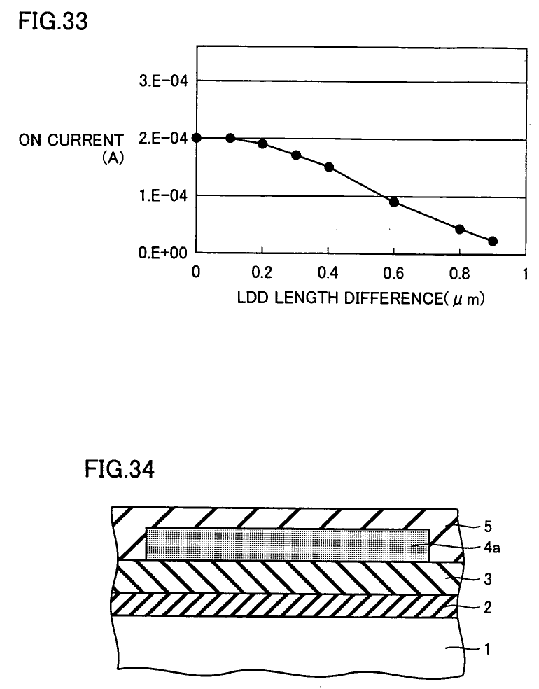

The results of the measurement of ON current in the thin film transistors produced as set forth above will be described hereinafter. FIG. 33 is a graph representing the dependency of ON current on the difference between the source side LDD length and drain side LDD length (LDD length difference). It is appreciated from FIG. 33 that the tendency of ON current becoming lower is noticeable with a large inclination in the graph when the LDD length difference exceeds 0.3 μm. Thus, the LDD length difference is preferably not more than 0.3 μm in order to ensure a predetermined ON current.

### Eighth Embodiment

An example of a p type thin film transistor will be described in the present embodiment. The process up to the step of forming the gate insulation film shown in FIG. 34 and implanting predetermined impurities to control the threshold value of the thin film transistor is similar to that of the process up to the step of FIG. 4 set forth before.

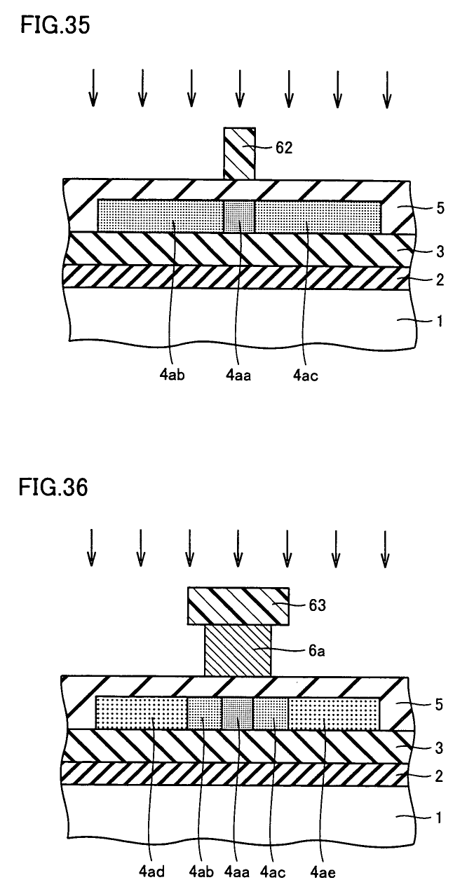

Referring to FIG. 35, predetermined photolithography is applied to form resist pattern 62 on gate insulation film 5. Using resist pattern 62 as a mask, boron is implanted with a dosage of 1×10¹³ atom/cm² and acceleration energy of 60 KeV, for example, to obtain impurity regions 4ab and 4ac identified as the GOLD region. The implanted amount thereof corresponds to the amount of implantation of the GOLD region. Then, ashing and chemical treatment are applied to remove resist pattern 62.

Through a step similar to the steps shown in FIGS. 6 and 7 set forth before, resist pattern 63 and gate electrode 6a are formed. Referring to FIG. 36, boron is implanted with a dosage of 1×10¹⁵ atom/cm² and acceleration energy of 60 KeV, for example, using resist pattern 63 as a mask to form impurity regions 4ad and 4ae identified as the source region and drain region. Then, ashing and chemical treatment are applied to remove resist pattern 63.

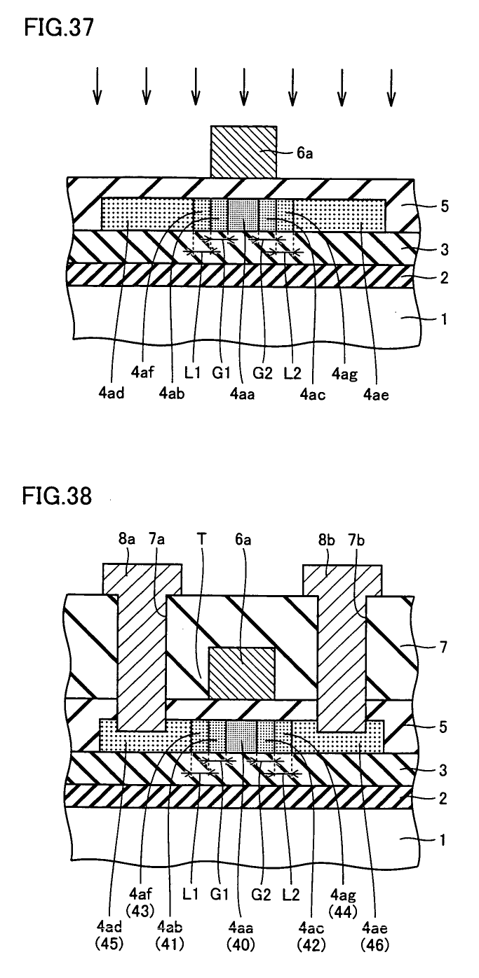

Referring to FIG. 37, boron is implanted with a dosage of 5×10¹³ atom/cm² and acceleration energy of 60 KeV, for example, using gate electrode 6a as a mask to obtain impurity regions 4af and 4ag identified as the LDD region. Accordingly, the impurity concentration of impurity regions 4af and 4ag identified as the LDD region becomes higher than that of impurity regions 4ab and 4ac identified as the GOLD region and lower than that of impurity regions 4ad and 4ae identified as the source region and drain region.

Then, a step similar to the step of FIG. 9 set forth before is carried out to produce a p channel thin film transistor of a GOLD structure, as shown in FIG. 38.

The measured results of source-drain breakdown voltage of the thin film transistor set forth above will be described here. For the measurement, a thin film transistor of the following parameters was employed: gate width 20 μm; effective gate length 5 μm; length of GOLD regions 41 and 42 in direction of channel length 1 μm, length of LDD regions 43 and 44 in direction of channel length 0.5 μm; and length of gate electrode 6a in direction of channel length 7 μm.

For comparison, a thin film transistor of a conventional LDD structure of the following parameters was employed: gate width 20 μm; gate length 5 μm; length of LDD region in direction of channel length 0.5 μm. Also, a thin film transistor of a conventional GOLD structure of the following parameters was employed: gate width 20 μm; gate length 5 μm; length of GOLD region in direction of channel length 1 μm; and length of gate electrode in direction of channel length 7 μm.

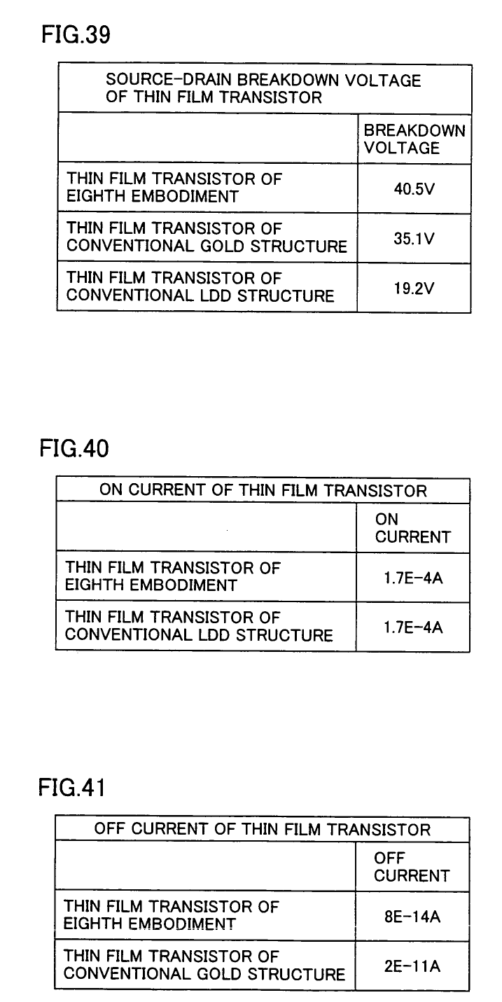

The measured results of source-drain breakdown voltage are shown in FIG. 39. The conditions of measurements and the like are similar to those set forth before. As shown in FIG. 39, it was confirmed that the source-drain breakdown voltage of the thin film transistor of a GOLD structure according to the eighth embodiment is higher than the source-drain breakdown voltage of thin film transistors of the conventional GOLD structure and conventional LDD structure.

Measured results of ON current will be described here. The conditions of measurement are similar to those set forth before. The measured results of ON current are shown in FIG. 40. It was confirmed that the thin film transistor of a GOLD structure of the eighth embodiment exhibits an ON current substantially equal to that of a thin film transistor of a conventional LDD structure that have LDD regions of the same length.

Measured results of OFF current will be described here. The conditions of measurements are similar to those set forth before. The measured results of OFF current are shown in FIG. 41. It was confirmed that the thin film transistor of a GOLD structure according to the eighth embodiment exhibits an OFF current lower than that of the thin film transistor of a conventional GOLD structure.

The range of the impurity concentration in the GOLD region, the length of the GOLD region in the direction of the channel length, the range of the impurity concentration in the LDD region, the length of the LDD region in the direction of the channel length, and the difference in the length between the LDD regions at the source side and drain side in the direction of the channel length for semiconductor devices in which the impurity concentration of the GOLD region is lower than that of the LDD region will be described in detail in the ninth to thirteenth embodiments hereinafter.

### Ninth Embodiment

The impurity concentration of the GOLD region in a thin film transistor will be described in the present embodiment. To obtain a range of the impurity concentration, thin film transistors having different impurity concentrations in the GOLD region were produced and the electrical property thereof was evaluated. Thin film transistors were produced according to a fabrication method similar to that described in the first embodiment. Specifically, the gate width is 10 μm, the gate length is 5 μm, the length of the GOLD region in the direction of the channel length is 1 μm, the length of the LDD region in the direction of the channel length is 0.5 μm, and the length of the gate electrode in the direction of the channel length is 7 μm in the produced thin film transistors.

The ion implantation conditions of impurities to form the LDD region were set to a dosage of 1×10¹³ atom/cm² and acceleration energy of 80 KeV. The impurity concentration of each of the GOLD region and LDD region was estimated based on the relationship between the implanted amount of impurity ions and impurity concentration, obtained by SIMS measurement as mentioned in the first embodiment.

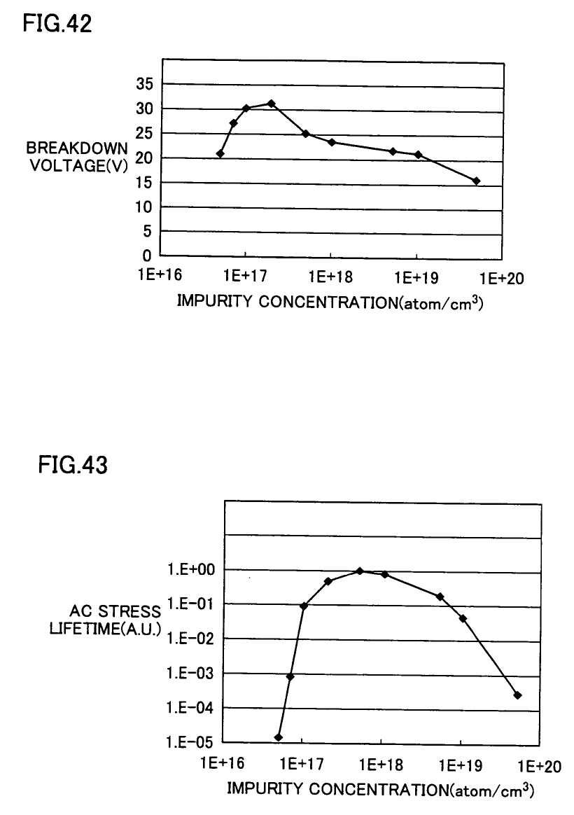

FIG. 42 is a graph representing the dependency of source-drain breakdown voltage on the impurity concentration of the GOLD region. As shown in FIG. 42, it is appreciated that the source-drain breakdown voltage is reduced, lower than the source-drain breakdown voltage of a thin film transistor of a conventional GOLD structure, when the impurity concentration of the GOLD region becomes higher than 1×10¹⁹ atom/cm³.

Therefore, the impurity concentration of the GOLD region is preferably set to not more than 1×10¹⁹ atom/cm³, and further preferably to at least 1×10¹⁷ atom/cm³ and not more than 1×10¹⁸ atom/cm³ to ensure a more stable breakdown voltage.

FIG. 43 is a graph representing the dependency of AC stress lifetime on the impurity concentration of the GOLD region. It is appreciated from FIG. 43 that a relatively favorable AC stress lifetime can be achieved when the impurity concentration of the GOLD region is in the range of at least 1×10¹⁷ atom/cm³ and not more than 1×10¹⁹ atom/cm². Further favorable AC stress lifetime can be achieved in the range of at least 5×10¹⁷ atom/cm³ and not more than 1×10¹⁸ atom/cm³.

Thus, from the standpoint of source-drain breakdown voltage and AC stress lifetime, the impurity concentration of the GOLD region is preferably set to at least 1×10¹⁷ atom/cm³ and not more than 1×10¹⁹ atom/cm³.

### Tenth Embodiment

The impurity concentration of the LDD region in a thin film transistor will be described in the present embodiment. To obtain a range of the impurity concentration, thin film transistors having different impurity concentrations in the LDD region were produced and the electrical property thereof was evaluated. Thin film transistors were produced according to a fabrication method similar to that described in the first embodiment. Thin film transistors were employed, wherein the gate width is 10 μm, the gate length is 5 μm, the length of the GOLD region in the direction of the channel length is 1 μm, the length of the LDD region in the direction of the channel length is 0.5 μm, and the length of the gate electrode in the direction of the channel length is 7 μm.

The ion implantation conditions of impurities to form the GOLD region were set to a dosage of 5×10¹² atom/cm² and acceleration energy of 80 KeV. The impurity concentration of each of the GOLD region and LDD region was estimated based on the relationship between the implanted amount of impurity ions and impurity concentration, obtained by SIMS measurement, as mentioned in the first embodiment.

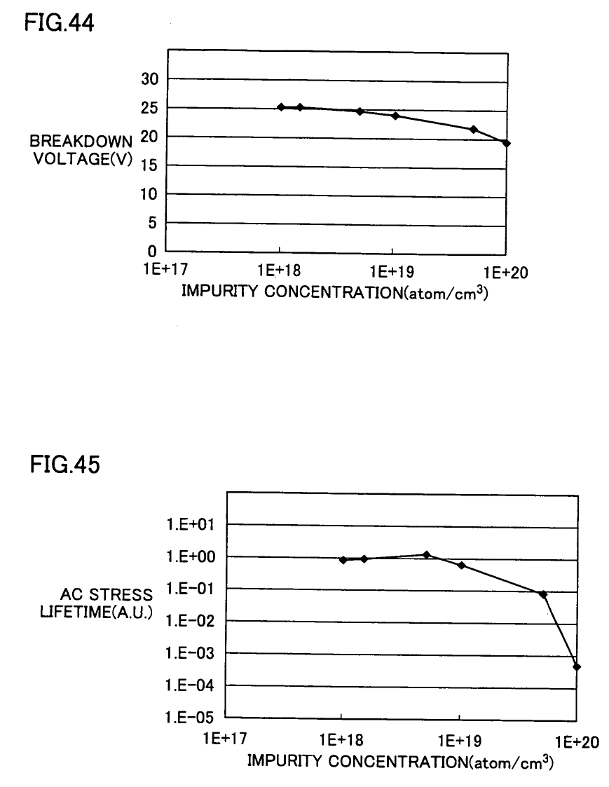

FIG. 44 is a graph representing the dependency of source-drain breakdown voltage on the impurity concentration of the LDD region. As shown in FIG. 44, it is appreciated that the source-drain breakdown voltage is reduced when the impurity concentration of the LDD region becomes higher than 5×10¹⁹ atom/cm³.

From the standpoint of source-drain breakdown voltage, the impurity concentration of the LDD region is preferably set to not more than 5×10¹⁹ atom/cm³ and further preferably not more than 1×10¹⁹ atom/cm³ to ensure a more stable breakdown voltage.

FIG. 45 is a graph representing the dependency of AC stress lifetime on the impurity concentration of the LDD region. It is appreciated from FIG. 45 that a relatively favorable AC stress lifetime can be achieved when the impurity concentration of the LDD region is not more than 5×10¹⁹ atom/cm³. Further favorable AC stress lifetime can be achieved at not more than 1×10¹⁹ atom/cm³.

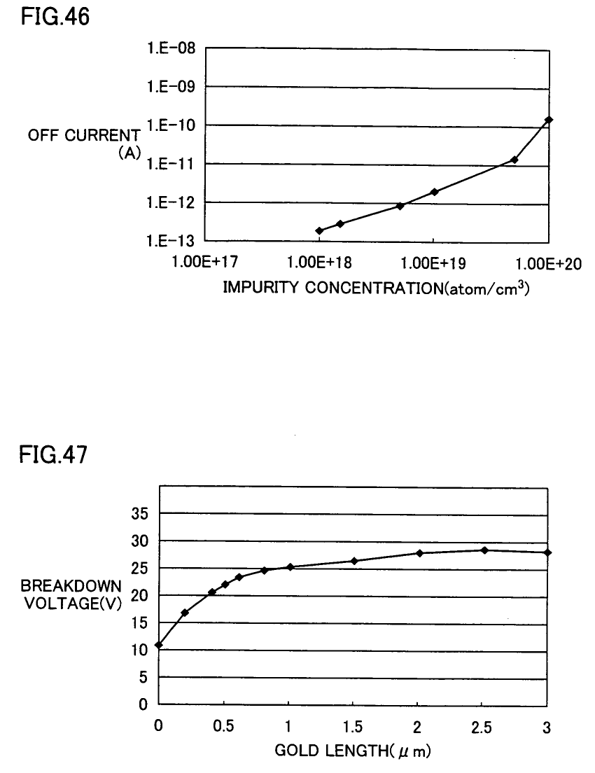

FIG. 46 is a graph representing the dependency of OFF current on the impurity concentration of the LDD region. It is appreciated from FIG. 46 that the OFF current increases as the impurity concentration of the LDD region becomes higher. From the standpoint of reducing OFF current, a lower impurity concentration in the LDD region is preferable. Thus, the impurity concentration of the LDD region is preferably set to not more than 5×10¹⁹ atom/cm³.

### Eleventh Embodiment

In the present embodiment, the length of the GOLD region in the direction of the channel length in a thin film transistor will be described. To obtain a range of the length of the GOLD region in the direction of the channel length (GOLD length), various thin film transistors with different GOLD lengths were fabricated, and the electrical property thereof was evaluated.

The thin film transistors were produced according to the fabrication method similar to that described in the first embodiment to have the following parameters: gate width 10 μm; gate length 5 μm; and length of LDD region in direction of channel length 0.5 μm. The length of the gate electrode in the direction of the channel length was varied in accordance with the length of the GOLD region in the direction of the channel length. The impurity concentration of the GOLD region was set to 5×10¹⁷ atom/cm³. The impurity concentration of the LDD region was set to 1.5×10¹⁸ atom/cm³.

FIG. 47 is a graph representing the dependency of source-drain breakdown voltage on the GOLD length. It is appreciated from FIG. 47 that the source-drain breakdown voltage drops abruptly when the GOLD length becomes shorter than 0.5 μm. The source-drain breakdown voltage exhibits no great change, and is apt to be saturated when the GOLD length exceeds 2 μm.

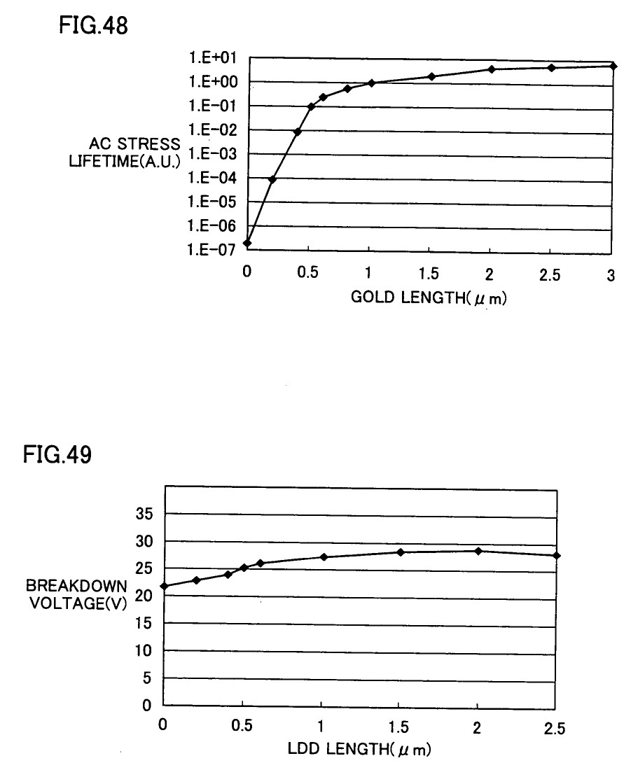

FIG. 48 is a graph representing the dependency of AC stress lifetime on the GOLD length. It is appreciated from FIG. 48 that the AC stress lifetime suddenly becomes shorter when the GOLD length is below 0.5 μm. The AC stress lifetime exhibits no great change, and is apt to be saturated when the GOLD length exceeds 2 μm.

Therefore, from the standpoint of source-drain breakdown voltage and AC stress, the GOLD length is preferably set to at least 0.5 μm. When the GOLD length exceeds 2 μm, both source-drain breakdown voltage and AC stress lifetime are apt to be saturated. Furthermore, the size of the thin film transistor will become larger to cause increase in the occupying area when the GOLD length exceeds 2 μm, which will become a factor to obviate reduction in the size of the semiconductor device. Therefore, the GOLD length is preferably set to at least 0.5 μm and not more than 2 μm.

### Twelfth Embodiment

The length of the LDD region in the direction of the channel length in a thin film transistor will be described in the present embodiment. To obtain a range of the length of the LDD region in the direction of the channel length (LDD length), various thin film transistors with different LDD lengths were produced, and the electric property thereof was evaluated.

The thin film transistors were produced according to a fabrication method similar to that described in the first embodiment, having the following parameters: gate width 10 μm; gate length 5 μm, length of GOLD region in direction of channel length 1 μm; and length of gate electrode in direction of channel length 7 μm. The impurity concentration of the GOLD region was set to 5×10¹⁷ atom/cm³. The impurity concentration of the LDD region was set to 1.5×10¹⁸ atom/cm³.

FIG. 49 is a graph representing the dependency of source-drain breakdown voltage on the LDD length. It is appreciated from FIG. 49 that the source-drain breakdown voltage is apt to be reduced when the LDD length becomes smaller than 0.5 μm. The source-drain breakdown voltage exhibits no great change, and is apt to be saturated when the LDD length exceeds 1.5 μm.

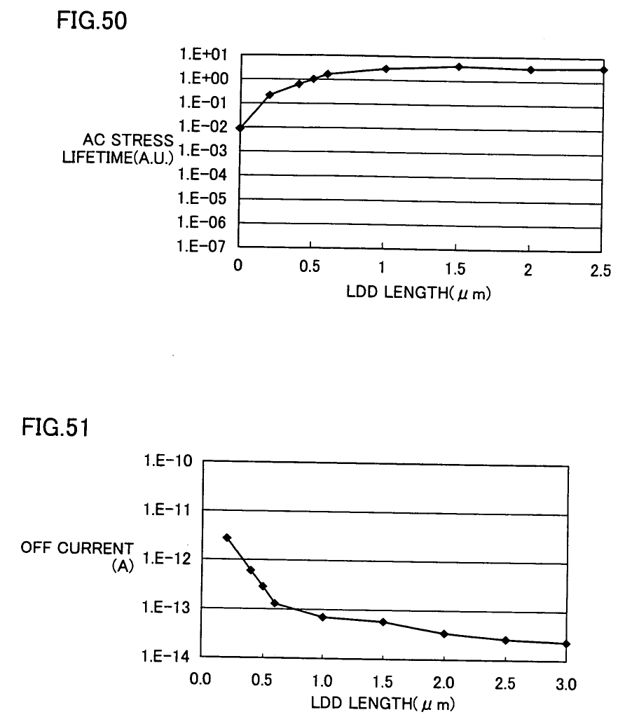

FIG. 50 is a graph representing the dependency of AC stress lifetime on the LDD length. It is appreciated from FIG. 50 that the AC stress lifetime is apt to become shorter when the LDD length is below 0.5 μm. The AC stress lifetime exhibits no great change, and is apt to be saturated when the LDD length exceeds 1.5 μm.

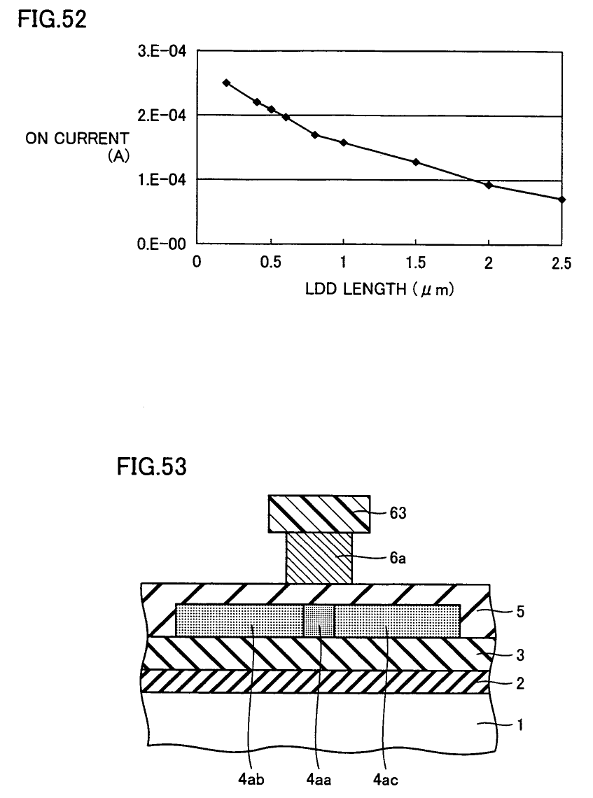

FIG. 51 is a graph representing the dependency of OFF current on the LDD length. It is appreciated from FIG. 51 that the OFF current is apt to be increased when the LDD length becomes smaller than 0.5 μm. The OFF current is apt to be gradually reduced as the LDD length becomes longer.

FIG. 52 is a graph representing the dependency of ON current on the LDD length. It is appreciated from FIG. 52 that the ON current is apt to be gradually reduced as the LDD length becomes longer. In view of the tendency of the OFF current, the LDD length is preferably set to not more than 1.5 μm in order to suppress the OFF current while ensuring a predetermined ON current.

Thus, from the standpoint of source-drain breakdown voltage, AC stress lifetime, and OFF current, the LDD length is preferably set to at least 0.5 μm. From the standpoint of ON current and OFF current, the LDD length is preferably set to not more than 1.5 μm. Thus, the LDD length is preferably set to at least 0.5 μm and not more than 1.5 μm.

### Thirteenth Embodiment

The difference in length in the direction of the channel length between the LDD region at the source side and the LDD region at the drain side in a thin film transistor will be described in the present embodiment. Difference in the length in the direction of the channel length between the LDD region at the source side and the LDD region at the drain side affects the ON current.

In the case where a predetermined voltage is applied to the gate and drain and the source is connected to ground, the voltage drop by the LDD region at the source side causes the voltage across the gate and source to become lower than the voltage applied to the gate. Since this voltage drop is due to the resistance of the LDD region at the source side, the drain current will also be reduced if the LDD length at the source side is longer in the direction of the channel length than the LDD length at the drain side. Therefore, it is preferable that the difference between the LDD length at the source side and the LDD length at the drain side is small.

In order to obtain a range of difference between the source side LDD length and drain side LDD length, various thin film transistors were produced according to the procedure set forth below, and the electrical property thereof was evaluated. The various thin film transistors produced have different source side LDD lengths based on a constant sum of the source side LDD length and the drain side LDD length.

The thin film transistors employed in the evaluation had the following parameters: gate width 10 μm, gate length 5 μm, length of GOLD region in direction of channel length 1 μm; and length of gate electrode in direction of channel length 7 μm. The impurity concentration of the GOLD region was set to 5×10¹⁷ atom/cm³. The impurity concentration of the LDD region was set to 1.5×10¹⁸ atom/cm³.

Through a process similar to that corresponding to the steps of FIGS. 2-7 described in the first embodiment, gate electrode 6a is formed using resist pattern 63 as a mask, as shown in FIG. 53. Then, resist pattern 63 is removed without effecting ion implantation for the formation of a source region and drain region with resist pattern 63 as a mask.

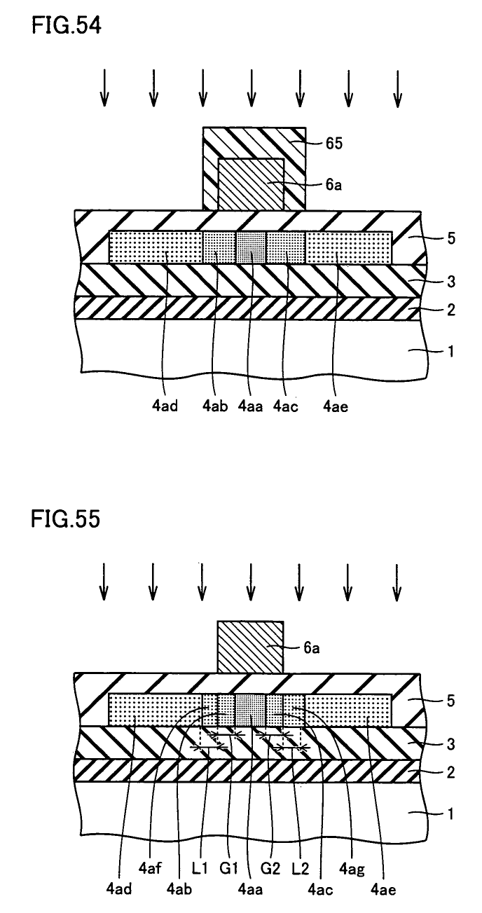

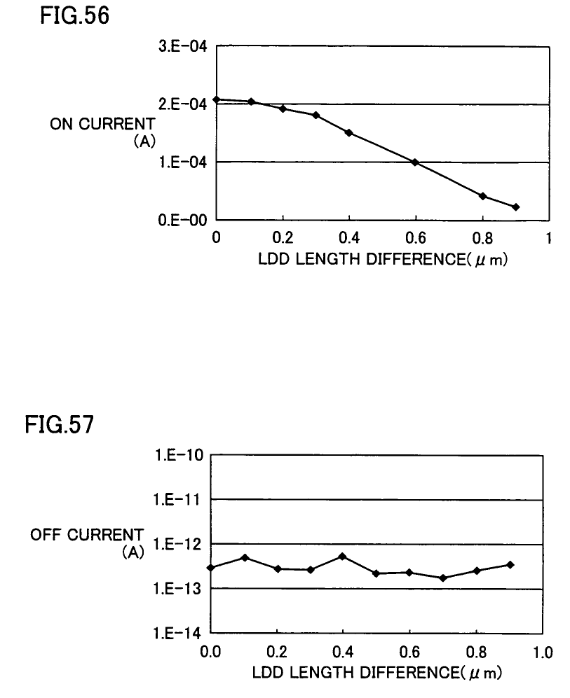

Referring to FIG. 54, a resist pattern 65 for the formation of a source region and drain region is newly formed. Resist pattern 65 is set to form an LDD region that has the source side LDD length vary in steps of 0.05 μm from 0.5 μm to 0.05 μm based on a constant sum of 1 μm (refer to FIG. 55) for the LDD region of the source side (L1) and the LDD length of the drain side (L2).

Using resist pattern 65 as a mask, phosphorus is implanted to obtain impurity regions 4ad and 4ae identified as the source region and drain region. Then, resist electrode 6a as a mask to obtain impurity regions 4af and 4ag identified as the LDD region.

Thus, thin film transistors for evaluation are produced, having impurity region 4af vary in LDD length from 0.5 μm to 0.05 μm in steps of 0.05 μm based on the sum of 1 μm for LDD length L1 of impurity region 4af identified as the source side LDD region and LDD length L2 of impurity region 4ag identified as the drain side LDD region.

Measured results of ON current for thin film transistors produced as set forth above will be described here. The measurement conditions are similar to those described before. With regards to the measured results of ON current, FIG. 56 is a graph representing the dependency of ON current on the difference between the source side LDD length and drain side LDD length (LDD length difference). As shown in FIG. 56, when the LDD length difference exceeds 0.3 μm, the tendency of reduction in ON current is noticeable with a larger inclination in the graph. Therefore, the LDD length difference is preferably set to not more than 0.3 μm to ensure a predetermined ON current.

FIG. 57 is a graph representing the dependency of OFF current on the LDD length difference. It is appreciated from FIG. 57 that the OFF current is substantially not dependent on the LDD length difference. Therefore, the LDD length difference is preferably set to not more than 0.3 μm.

### Fourteenth Embodiment

The present embodiment is directed to an example of a thin film transistor including two gate electrodes as a thin film transistor. Although two thin film transistors will be substantially formed by the provision of two gate electrodes, an operation similar to that of one thin film transistor is achieved in function by establishing electrical connection between the drain of one thin film transistor and the source of the other thin film transistor and also between the gate electrode of one thin film transistor and the gate electrode of the other thin film transistor.

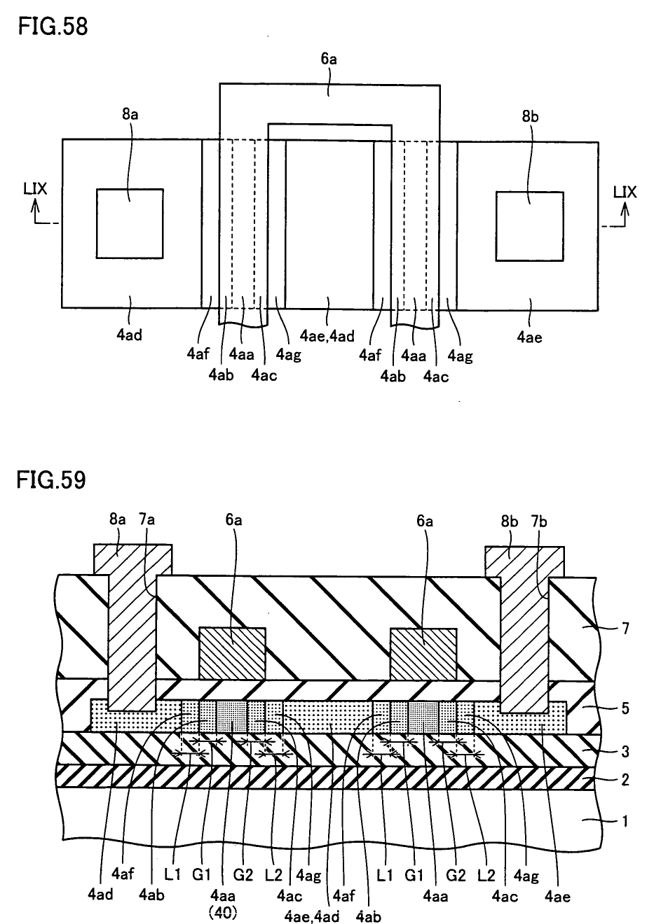

From the structure perspective, two of a thin film transistor T shown in FIG. 1, for example, are formed at one island-shaped polycrystalline silicon film. Specifically, as shown in FIGS. 58 and 59, two thin film transistors are formed, each thin film transistor T including impurity region 4ad and impurity region 4ae identified as a source region and a drain region, respectively, impurity regions 4af and 4ag identified as the LDD region, impurity regions 4ab and 4ac identified as the GOLD region, impurity region 4aa identified as the channel region, and gate electrode 6. The remaining configuration is similar to that shown in FIG. 1. The same elements have the same reference characters allotted, and description thereof will not be repeated.

The thin film transistor set forth above can be produced by a fabrication method similar to that described in the first embodiment by just modifying the pattern corresponding to the gate electrode.

Measured results of OFF current for the thin film transistor set forth above will be described hereinafter. For the measurement, a thin film transistor was employed having the following parameters: gate width 10 μm, gate length of respective gate electrodes 5 μm; length of GOLD regions 41 and 42 in direction of channel length 1 μm; length of LDD regions 43 and 44 in direction of channel length 0.5 μm; and length of respective gate electrodes in direction of channel length 7 μm. The impurity concentration of the GOLD region was set to 5×10¹⁷ atom/cm³. The impurity concentration of the LDD region was set to 1.5×10¹⁸ atom/cm³.

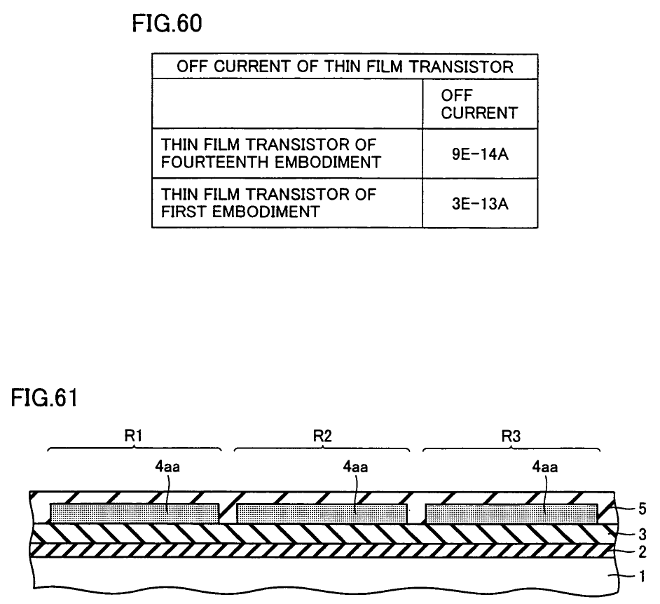

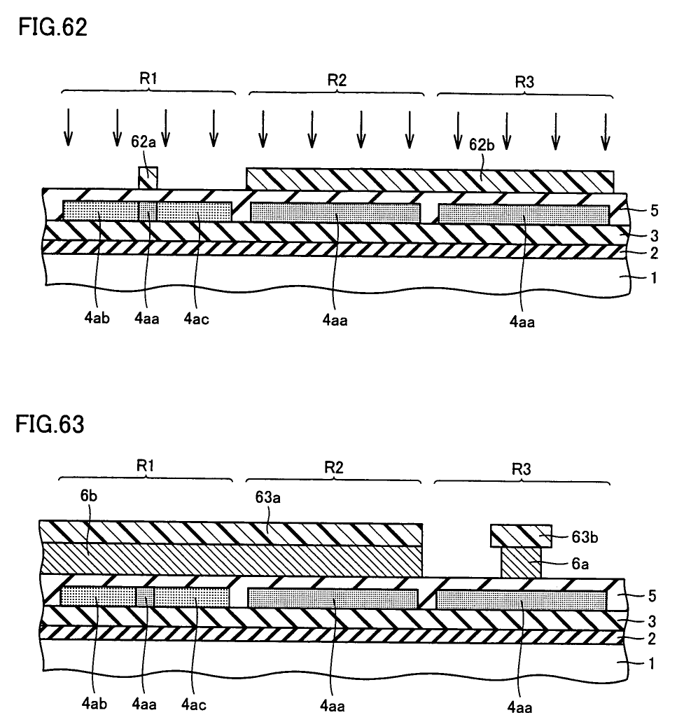

The measured results of OFF current are shown in FIG. 60. It is appreciated from FIG. 60 that the thin film transistor of the fourteenth embodiment can have the OFF current further reduced, as compared to the thin film transistor described in the first embodiment. In addition to the OFF current, it was identified that the thin film transistor of the fourteenth embodiment exhibited source-drain breakdown voltage and AC stress lifetime of a level identical to that of the thin film transistor of the first embodiment.

The present invention is not limited to the above-described thin film transistor having two gate electrodes 6a. The OFF current can be further reduced by increasing the number of gate electrodes under the allowable size in the region where the thin film transistor is formed.

### Fifteenth Embodiment

The fifteenth embodiment is directed to an example of a semiconductor device including a thin film transistor of a GOLD structure, a thin film transistor of an LDD structure, and a general thin film transistor. A fabrication method of such a semiconductor device will be described first.

In a manner similar to that described in the first embodiment, silicon nitride film 2 and silicon oxide film 3 are formed on glass substrate 1, as shown in FIG. 61. An island-shaped polycrystalline silicon film is formed on each region of silicon oxide film 2 corresponding to predetermined regions R1-R3 where respective thin film transistors are to be formed at glass substrate 1. A thin film transistor of a different type is to be formed at each of regions R1-R3.

A gate insulation film 5 of a silicon oxide film is deposited so as to cover the polycrystalline silicon film. Then, boron is implanted into the polycrystalline silicon film with a dosage of 1×10¹² atom/cm² and acceleration energy of 60 KeV, for example, to control the threshold value of the thin film transistor, whereby island-shaped impurity regions 4aa are provided.

Referring to 62, predetermined photolithography is applied to form a resist pattern 62a required to provide a thin film transistor of an n type GOLD structure at region R1, and to form a resist pattern 62b covering the area of regions R2 and R3 where an n type thin film transistor of an LDD structure and a general p type thin film transistor are to be formed, respectively.

Using resist patterns 62a and 62b as masks, phosphorus is implanted into impurity regions 4aa with a dosage of 5×10¹² atom/cm² and acceleration energy of 80 KeV, for example, whereby impurity regions 4ab and 4ac are obtained at region R1. The implanted amount thereof corresponds to the amount of implantation of the GOLD region. Then, ashing and chemical treatment are applied to remove resist patterns 62a and 62b.

Then, a chromium film of approximately 400 nm in film thickness (not shown) is formed all over gate insulation film 5 by sputtering. Predetermined photolithography is applied to form a resist pattern 63b required to create a pattern of a gate electrode at region R3, and to form a resist pattern 63a all over in regions R1 and R2 (refer to FIG. 63).

Using resist patterns 63a and 63b as masks, the chromium film is subjected to wet etching, whereby gate electrode 6a is obtained at region R3, as shown in FIG. 63. Chromium film 6b at regions R1 and R2 remains. Then, ashing and chemical treatment are applied to remove resist patterns 63a and 63b.

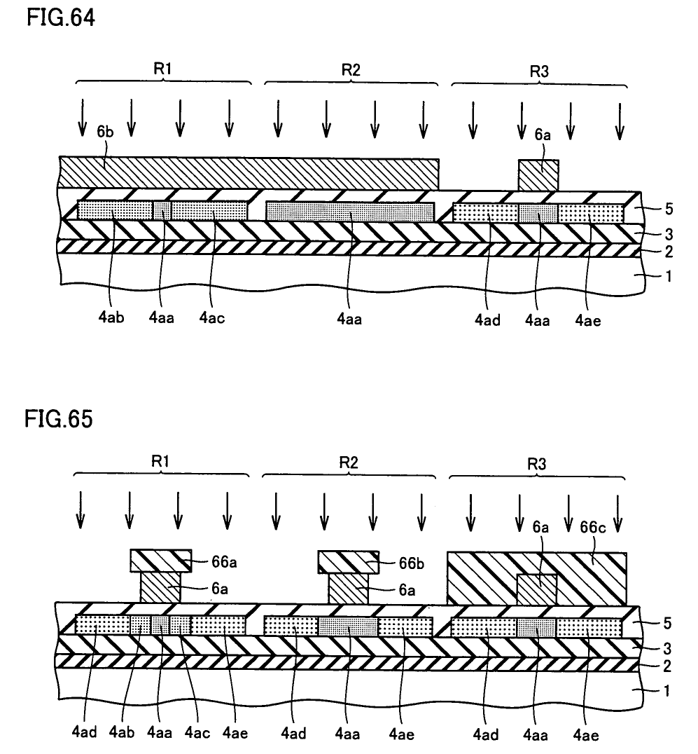

Referring to FIG. 64, using the remaining chromium film 6b and gate electrode 6a as masks, boron is implanted with a dosage of 1×10¹⁵ atom/cm² and acceleration energy of 60 KeV, for example, to form impurity regions 4ad and 4ae identified as the source region and drain region, respectively, of a p type thin film transistor at impurity region 4aa located in region R3. At this stage, boron is not implanted into regions R1 and R2 since the area is covered by chromium film 6b.

Then, predetermined photolithography is applied to form resist patterns 66a and 66b required to create a pattern of a gate electrode at regions R1 and R2, and to form resist pattern 66c all over in region R3 (refer to FIG. 65).

At this stage, resist pattern 66a at region R1 is formed so as to overlap in plane with impurity regions 4ab and 4ac. The overlapping region in plane between resist pattern 66a and impurity regions 4ab and 4ac is identified as the GOLD region.

Using resist patterns 66a, 66b and 66c as masks, chromium film 6b is etched, resulting in a gate electrode 6a at each of regions R1 and R2, as shown in FIG. 65. At this stage, gate electrode 6a located at region R1 is formed so as to overlap in plane with impurity regions 4ab and 4ac. Furthermore, gate electrode 6a formed at region R3 is not subjected to etching since it is covered with resist pattern 66c.

Application of wet etching allows the side surface of the chromium film identified as the gate electrode to be etched away. The amount of etching thereof can be controlled by the duration of overetching.

Using the remaining resist patterns 66a, 66b and 66c as masks, phosphorus is implanted with a dosage of 1×10¹⁴ atom/cm² and acceleration energy of 80 KeV, for example, to obtain an impurity region 4ad and an impurity region 4ae identified as a source region and drain region, respectively, of an n type thin film transistor of a GOLD structure at impurity regions 4ab and 4ac, respectively, located at region R1.

At impurity region 4aa located at region β2, impurity region 4ad and impurity region 4ae identified as the source region and drain region, respectively, of an n type thin film transistor of a LDD structure are obtained. At this stage, phosphorus is not implanted into region R3 due to the coverage of resist pattern 66c. Then, ashing and chemical treatment are applied to remove resist patterns 66a, 66b and 66c.

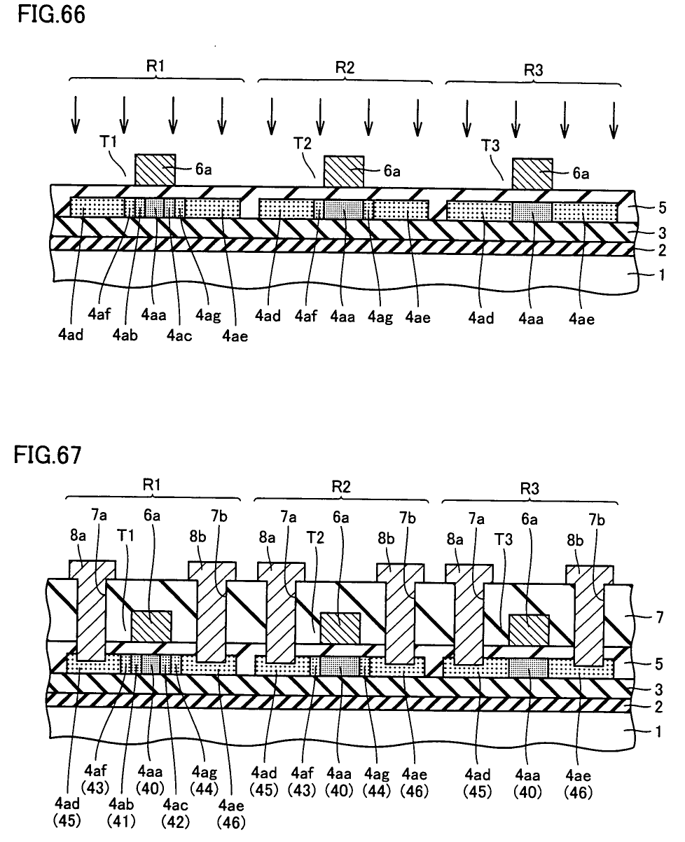

Referring to FIG. 66, using gate electrode 6a as a mask, phosphorus is implanted with a dosage of 1×10¹³ atom/cm² and acceleration energy of 80 KeV, for example, to obtain impurity region 4af and impurity region 4ag identified as the LDD regions at the source side and the drain side, respectively, of an n type thin film transistor of a GOLD structure at the remaining impurity regions 4ab and 4ac, respectively, located at region R1.

At the area of remaining impurity regions 4aa at region β2, impurity region 4af and impurity region 4ag identified as to the LDD regions at the source side and drain side, respectively, of an n type thin film transistor of an LDD structure are obtained.

Although phosphorus is implanted also into boron-implanted impurity regions 4ad and 4ae identified as the source region and drain region, respectively, of the p type thin film transistor at region R3, implantation of phosphorus into impurity regions 4ad and 4ae at region R3 is of no concern since the implanted amount of phosphorus is sufficiently smaller than the implanted amount of boron.

In a manner similar to that described in the first embodiment, an interlayer insulating film 7 of a silicon oxide film is deposited on glass substrate 1, as shown in FIG. 67. Interlayer insulation film 7 is then subjected to predetermined photolithography, whereby a resist pattern (not shown) required to produce a contact hole is formed.

Using that resist pattern as a mask, interlayer insulation film 7 and gate insulation film 5 are subjected to anisotropic etching, whereby a contact hole 7a exposing the surface of impurity region 4ad and a contact hole 7b exposing the surface of impurity region 4ae are formed at regions R1-R3.

Then, a multilayer film of chromium and aluminum (not shown) is formed on interlayer insulation film 7 so as to fill contact holes 7a and 7b. Predetermined photolithography is applied on the multilayer film to form a resist pattern (not shown) required to produce an electrode. Using that resist pattern as a mask, wet etching is applied to result in source electrode 8a and drain electrode 8b at respective regions R1-R3.

Thus, an n type thin film transistor T1 of a GOLD structure, an n type thin film transistor T2 of an LDD structure, and a general p type thin film transistor T3 are formed at regions R1, R2, and R3, respectively.

At n type thin film transistor T1 of a GOLD structure, impurity region 4ad and impurity region 4ae are identified as source region 45 and drain region 46, respectively. Impurity regions 4ab and 4ac are identified as GOLD regions 41 and 42. Impurity regions 4af and 4ag are identified as LDD regions 43 and 44.

At n type thin film transistor T2 of an LDD structure, impurity region 4ad and impurity region 4ae are identified as source region 45 and drain region 46, respectively. Impurity regions 4af and 4ag are identified as LDD regions 43 and 44. At p type thin film transistor T3, impurity region 4ad and impurity region 4ae are identified as source region 45 and drain region 46, respectively.

By virtue of the above-described fabrication method, an advantage set forth below can be achieved, in addition to the advantage described in the first embodiment. When an n type thin film transistor of a GOLD structure and a general p type thin film transistor are to be formed by the conventional method, n type impurities of high concentration will be implanted into the source region and drain region of the p type thin film transistor. There was a problem that the resistance at the source region and drain region of the p type thin film transistor is increased.

In the fabrication method of the present embodiment, following formation of the source region and drain region of a p type thin film transistor, the resist pattern corresponding to the implantation mask is formed so as to cover the p type thin film transistor in the step of forming respective source regions and drain regions of an n type thin film transistor of a GOLD structure and an n type thin film transistor of an LDD structure.

Therefore, n type impurities of high concentration will not be implanted into the source region and drain region of the p type thin film transistor. The problem of the resistance at the source region and drain region of the p type thin film transistor being increased can be obviated.

When the length of the GOLD region has to be modified to reflect modification, for example, in the specification, the conventional method is disadvantageous in that the process condition to form the gate electrode in a tapered shape must be modified in addition to the modification of the mask pattern. In other words, the process condition to form a tapered gate electrode must be newly set to the optimum condition in conformance with the modification of the mask pattern since the etching reaction and the deposition reaction of the product must be adjusted, and this reaction will vary greatly depending upon the pattern and etching area.

The above-described method of the present embodiment allows a desired semiconductor device to be developed in a short period of time since modification in the GOLD length can be accommodated by just modifying the mask pattern.

The present invention is not limited to the above-described method in which a thin film transistor of a single drain structure is employed as the p type thin film transistor. A p type thin film transistor of an LDD structure can be formed by implanting impurities into the source region and drain region without removing the resist pattern after the gate electrode of the p type thin film transistor has been formed, and then removing the resist pattern to conduct ion implantation of impurities for the formation of an LDD film.

### Sixteenth Embodiment

As another example of a semiconductor device including a thin film transistor of a GOLD structure, a thin film transistor of an LDD structure, and a general thin film transistor, the present embodiment is directed to a semiconductor device including a p type thin film transistor of a GOLD structure in addition to the above-described n type thin film transistor of a GOLD structure. First, a fabrication method thereof will be described.

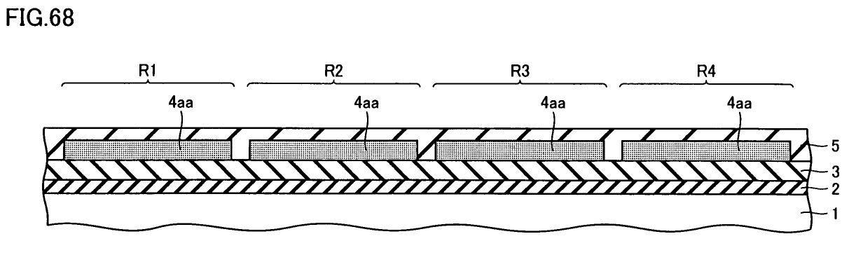

Through a method similar to that described in the first embodiment, silicon nitride film 2 and silicon oxide film 3 are formed on glass substrate 1, as shown in FIG. 68. An island-shaped polycrystalline silicon film is formed on each region of silicon oxide film 2 corresponding to predetermined regions R1-R4 where respective transistors are to be formed at glass substrate 1. A thin film transistor of a different type is to be formed at each of regions R1-R4.

A gate insulation film 5 of a silicon oxide film is formed so as to cover the polycrystalline silicon film. Then, boron is implanted into the polycrystalline silicon film with a dosage of 1×10¹² atom/cm³ and acceleration energy of 60 KeV, for example, to control the threshold voltage of the thin film transistor, whereby island-shaped impurity regions 4aa are provided.

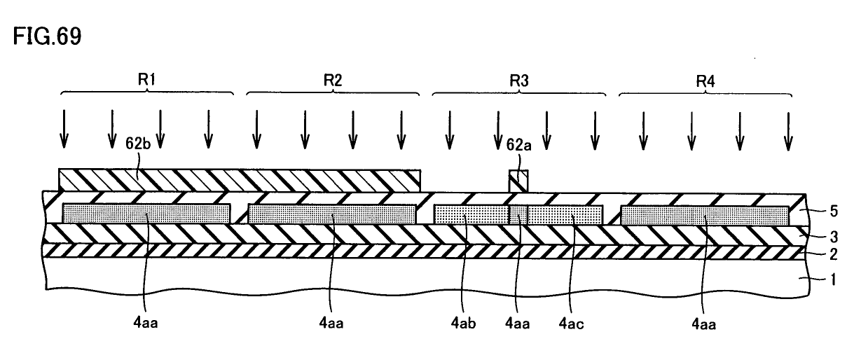

Referring to FIG. 69, predetermined photolithography is applied to form a resist pattern 62a required to provide a p type thin film transistor of a GOLD structure at region R3, and to form a resist pattern 62b covering the area of regions R1 and R2 where an n type thin film transistor of a GOLD structure and an n type thin film transistor of an LDD structure are to be formed, respectively. No particular resist pattern is formed at region R4 where a p type thin film transistor of an LDD structure is to be formed.

Using resist patterns 62a and 62b as masks, boron is implanted with a dosage of 1×10¹³ atom/cm² and acceleration energy of 60 KeV, for example, to obtain impurity regions 4ab and 4ac at region R3. The implanted amount thereof corresponds to the amount of implantation of the GOLD region. Then, ashing and chemical treatment are applied to remove resist patterns 62a and 62b.

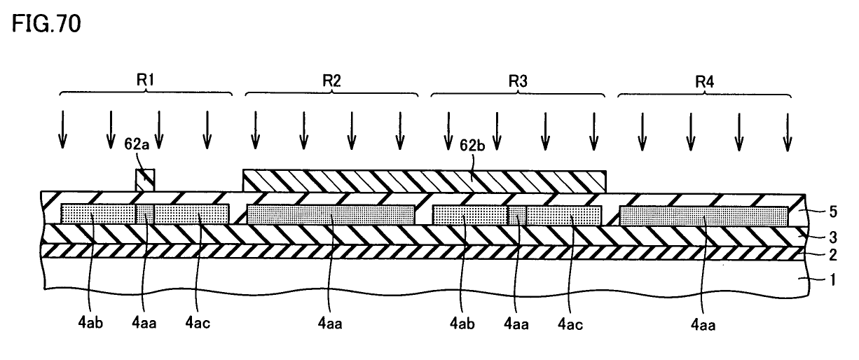

Referring to FIG. 70, predetermined photolithography is applied to form a resist pattern 62a required to form an n type thin film transistor of a GOLD structure at region R1, and to form resist pattern 62b covering regions R2 and R3 where an n type thin film transistor of an LDD structure and a p type thin film transistor of a GOLD structure are to be formed, respectively. No particular resist pattern is formed at region R4 where a p type thin film transistor of an LDD structure is to be formed.

Using resist patterns 62a and 0.62b as masks, phosphorus is implanted with a dosage of 5×10¹² atom/cm² and acceleration energy of 80 KeV, for example, to obtain impurity regions 4ab and 4ac at region R1. The implanted amount thereof corresponds to the amount of implantation of the GOLD region in the n type thin film transistor. Then, ashing and chemical treatment are applied to remove resist patterns 62a and 62b.

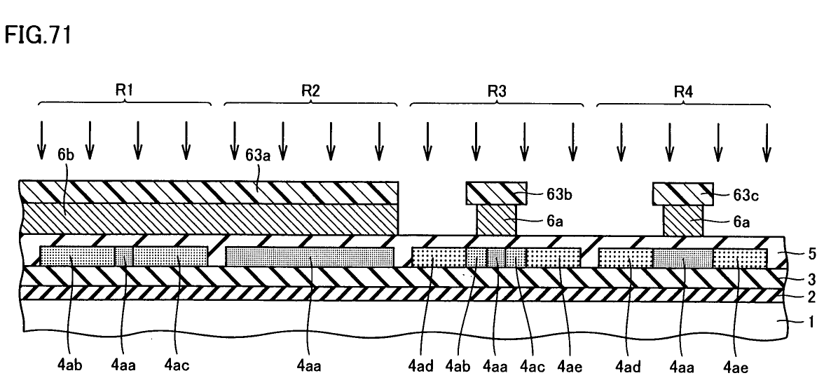

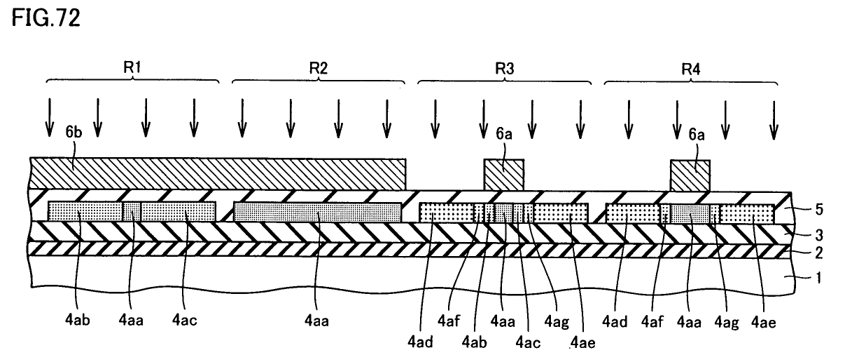

Then, a chromium film of approximately 400 nm in thickness (not shown) is formed all over gate insulation film 5 by sputtering. Then, predetermined photolithography is applied to form resist patterns 63b and 63c required to pattern a gate electrode at regions R3 and R4, respectively, and to form a resist pattern 63a covering regions R1 and R2 (refer to FIG. 71).

Referring to FIG. 71, the chromium film is subjected to wet etching, using resist patterns 63a, 63b and 63c as masks, to obtain gate electrode 6a at each of regions R3 and R4. Chromium film 6b at regions R1 and R2 remain. Resist pattern 63b at region R3 is formed so as to overlap in plane with impurity regions 4ab and 4ac. The overlapping region in plane with gate electrode 6a at impurity regions 4ab and 4ac is identified as the GOLD region.

By applying wet etching, the side surface of the chromium film identified as the gate electrode is etched away. The etched amount thereof can be controlled by the period of time of overetching.

Using remaining resist patterns 63a, 63b and 63c as masks, boron is implanted with a dosage of 1×10¹⁵ atom/cm² and acceleration energy of 60 KeV, for example, to obtain impurity region 4ad and impurity region 4ae identified as the source region and drain region, respectively, of the p type thin film transistor of a GOLD structure at impurity regions 4ab and 4ac located at region R3, and to obtain impurity region 4ad and impurity region 4ae identified as the source region and drain region, respectively, of the p type thin film transistor of an LDD structure at impurity region 4aa located at region R4.

Since region R1 where an n type thin film transistor of a GOLD structure is to be formed and region R2 where an n type thin film transistor of an LDD structure is to be formed are covered with resist pattern 63a, boron will not be implanted into regions R1 and R2. Then, ashing and chemical treatment are applied to remove resist patterns 63a, 63b, and 63c.

Referring to FIG. 72, boron is implanted with a dosage of 5×10¹³ atom/cm² and acceleration energy of 60 KeV for example, using gate electrode 6a as a mask, to obtain impurity region 4af and impurity region 4ag identified as the source side LDD structure and drain side LDD region, respectively, of the p type thin film transistor of a GOLD structure at regions of impurity regions 4ab and 4ac remaining at region R3. Also, impurity region 4af and impurity region 4ag identified as the source side LDD region and drain side LDD region, respectively, of the p type thin film transistor of an LDD structure are formed at a region of impurity region 4aa remaining at region R4.

The impurity concentration of impurity regions 4af and 4ag identified as the LDD region is set higher than that of impurity regions 4ab and 4ac identified as GOLD regions, and lower than that of impurity regions 4ad and 4ae identified as the source region and drain region, respectively.

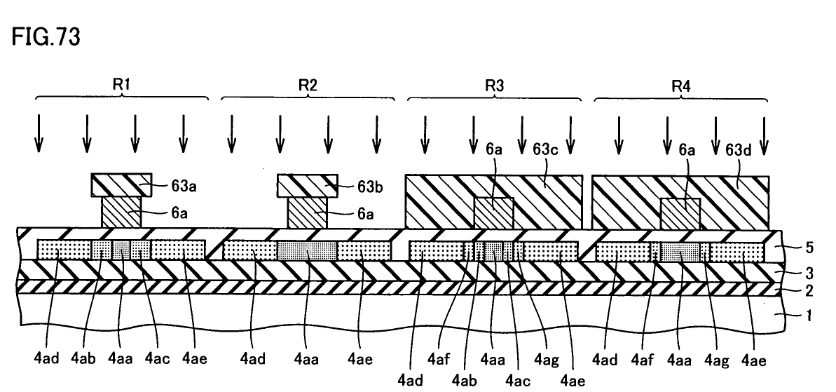

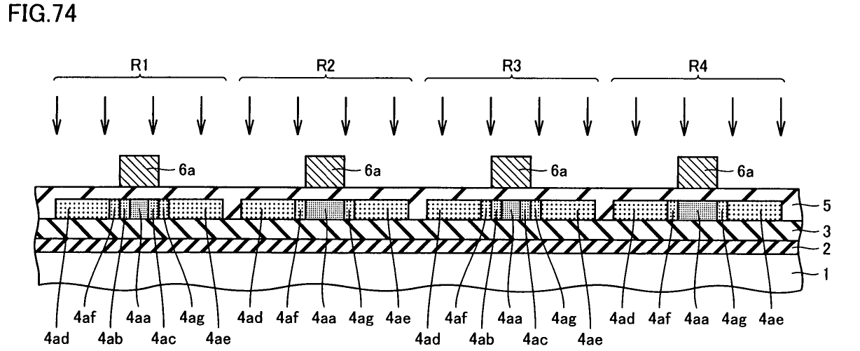

Then, predetermined photolithography is applied to form resist patterns 63a and 63b required to pattern a gate electrode at regions R1 and R2, respectively, and to form resist patterns 63c and 63d covering the area of regions R3 and R4 (refer to FIG. 73).

Referring to FIG. 73, the chromium film is subjected to wet etching using resist patterns 63a, 63b, 63c as masks to form gate electrode 6a at each of regions R1 and R2. At regions R3 and R4, gate electrode 6a is not subjected to etching since regions R3 and R4 are covered with resist patterns 63c and 63d, respectively.

At this stage, resist pattern 63a at region R1 is formed so as to overlap in plane with impurity regions 4ab and 4ac. The region overlapping in plane with gate electrode 6a at impurity regions 4ab and 4ac is identified as the GOLD regions. By applying wet etching, the side surface of the chromium film identified as the gate electrode is etched away. The etched amount thereof can be controlled by the period of time of overetching.

Using remaining resist patterns 63a, 63b and 63c as masks, phosphorus is implanted with a dosage of 1×10¹⁴ atom/cm² and acceleration energy of 80 KeV, for example, to obtain an impurity region 4ad and an impurity region 4ae identified as the source region and drain region, respectively, of an n type thin film transistor of a GOLD structure at impurity regions 4ab and 4ac located at region R1, and to obtain impurity region 4ad and impurity region 4ae identified as the source region and drain region, respectively, of the n type thin film transistor of an LDD structure at impurity regions 4aa located at region R2.

Since region R3 where the p type thin film transistor of a GOLD structure is formed and region R4 where the p type thin film transistor of an LDD structure is formed are covered with resist patterns 63c and 63d, respectively, phosphorus will not be implanted into regions R3 and R4. Then, ashing and chemical treatment are applied to remove resist patterns 63a, 63b and 63c.

Referring to FIG. 74, phosphorus is implanted with a dosage of 1×10¹³ atom/cm² and acceleration energy of 80 KeV, for example, using gate electrode 6a as a mask, to obtain impurity region 4af and impurity region 4ag identified as the source side LDD region and drain side LDD region, respectively, of the n type thin film transistor of a GOLD structure at impurity regions 4ab and 4ac remaining at region R1. Furthermore, impurity region 4af and impurity region 4ag identified as the source side LDD region and drain side LDD region, respectively, of the n type thin film transistor of an LDD structure are obtained at a portion of impurity region 4aa remaining at region R1.

Although phosphorus is implanted into boron-implanted impurity regions 4ad and 4ae identified as the source region and drain region, respectively, of the p type thin film transistor of a GOLD structure located at region R3 and the p type thin film transistor of an LDD structure located at region R4, implantation of phosphorus into impurity regions 4ad and 4ae at regions R3 and R4 is of no concern since the implanted amount of phosphorus is sufficiently smaller than the implanted amount of boron.

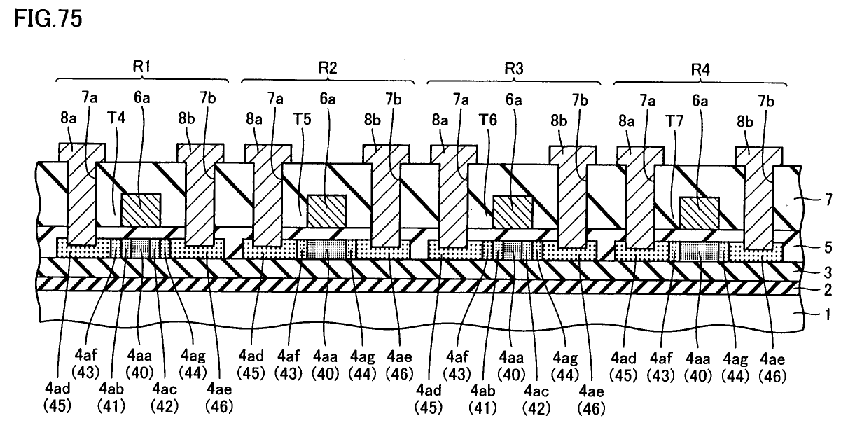

Then, in a manner similar to that described in the first embodiment, interlayer insulation film 7 of a silicon oxide film is deposited on glass substrate 1, as shown in FIG. 75. Interlayer insulation film 7 is then subjected to predetermined photolithography, whereby a resist pattern (not shown) required to produce a contact hole is formed.

Using that resist pattern as a mask, interlayer insulation film 7 and gate insulation film 5 are subjected to anisotropic etching, whereby a contact hole 7a and a contact hole 7b exposing the surface of impurity region 4ad and impurity region 4ae, respectively, located at each of regions R1 and R4, are formed.

Then, a multilayer film of chromium and aluminum (not shown) is formed on interlayer insulation film 7 so as to fill contact holes 7a and 7b. Predetermined photolithography is applied on the multilayer film to form a resist pattern (not shown) required to produce an electrode. Using that resist pattern as a mask, wet etching is applied to result in a source electrode 8a and a drain electrode 8b at respective regions R1-R4.

Thus, an n type thin film transistor T4 of a GOLD structure, an n type thin film transistor T5 of an LDD structure, a p type thin film transistor T6 of a GOLD structure, and a p type thin film transistor T7 of an LDD structure are provided at region R1, region R2, region R3, and region R4, respectively.

At n type thin film transistor T4 of a GOLD structure, impurity region 4ad is identified as source region 45. Impurity region 4ae is identified as drain region 46. Impurity regions 4ab and 4ac are identified as GOLD regions 41 and 42, respectively. Impurity regions 4af and 4ag are identified as LDD regions 43 and 44, respectively.

At n type thin film transistor T5 of an LDD structure, impurity region 4ad is identified as source region 45. Impurity region 4ae is identified as drain region 46. Impurity regions 4af and 4ag are identified as LDD regions 43 and 44, respectively.

At p type thin film transistor T6 of a GOLD structure, impurity region 4ad is identified as source region 45. Impurity region 4ae is identified as drain region 46. Impurity regions 4ab and 4ac are identified as GOLD regions 41 and 42, respectively. Impurity regions 4af and 4ag are identified as LDD regions 43 and 44, respectively.

At p type thin film transistor T7 of an LDD structure, impurity region 4ad is identified as source region 45. Impurity region 4ae is identified as drain region 46. Impurity regions 4af and 4ag are identified as LDD regions 43 and 44, respectively.

In accordance with the fabrication method set forth above, an n type thin film transistor of a GOLD structure, an n type thin film transistor of an LDD structure, a p type thin film transistor of a GOLD structure, and a p type thin film transistor of an LDD structure can be formed simultaneously by just adding a mask directed to formation of a gate electrode of a p type thin film transistor.

### Seventeenth Embodiment

A liquid crystal display device will be described hereinafter employing a semiconductor device including a thin film transistor. First, the structure of a liquid crystal display device will be described.

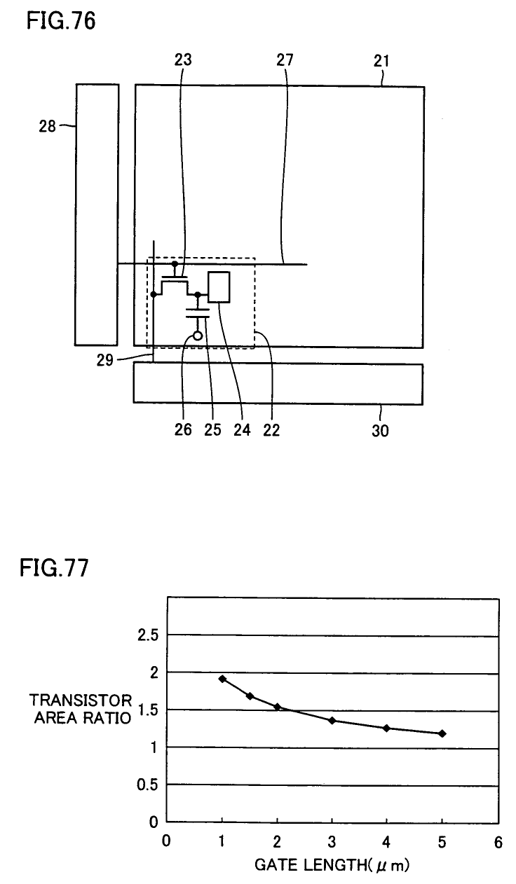

Referring to FIG. 76, the liquid crystal display device includes a display unit 21 formed of a plurality of pixels 22 for displaying an image, and a scanning line driving circuit unit 28 and a data line driving circuit unit 30 to control the operation of a pixel region thin film transistor 23 provided at each of pixels 22. Display unit 21 identified as a pixel region as well as scanning line driving circuit unit 28 and data line driving circuit unit 30 identified as the driving circuit unit constitute an image display circuit unit.

Pixels 22 are arranged in an array in display unit 21. In a pixel 22, pixel capacitance (not shown) is formed having liquid crystal (not shown) filled between a pixel electrode 24 and a counter electrode (not shown). The voltage applied to the liquid crystal is determined by the voltage applied across pixel electrode 24 and the counter electrode. The liquid crystal alignment status is altered by the voltage applied to the liquid crystal, whereby the intensity of light transmitted through the liquid crystal is controlled. Storage capacitance 25 is formed between pixel region thin film transistor 23 and common electrode 26.

Pixels 22 arranged in an array are connected to respective data lines 29 connected to data line driving circuit unit 30 and respective scanning lines 27 connected to scanning line driving circuit unit 28. A pixel signal is output from data line driving circuit unit 30. The output pixel signal is applied to pixel 22 via data line 29. Scanning line driving circuit unit 28 outputs a pixel select signal which is provided to pixel 22 via scanning line 27.

Scanning line driving circuit unit 28 mainly includes a shift register and an output circuit. The register is shifted by an input clock signal. When the register attains a high (H) level, the output circuit is switched to an ON voltage of pixel 22. When the register attains a low (L) level, the output circuit is switched to an OFF voltage of pixel 22. Accordingly, scanning line driving circuit unit 28 sequentially applies an ON voltage and an OFF voltage to the scanning line of pixel 22.

Data line scanning circuit unit 30 sequentially latches an input pixel data signal (for example, 6t-bit pixel data) in accordance with the timing of the clock signal. The input pixel data is converted into an analog signal by a DA converter in data line driving circuit unit 30. The pixel data converted into an analog signal is sent onto data line 29.

The gate of pixel region thin film transistor 23 of pixel 22 is controlled by the signal sent from scanning line 27. When an ON signal is applied to the gate and the gate of the pixel thin film transistor is turned ON, the signal delivered from data line 29 is accumulated in the pixel capacitance and storage capacitance 25. The accumulated signal is retained in the pixel capacitance and storage capacitance for the duration of one frame until the gate is turned OFF and the screen is rewritten.

If leakage current occurs at the pixel thin film transistor at this stage, the voltage applied to the liquid crystal will be decreased over the retaining time to degrade the display quality of display unit 21. It is therefore necessary to minimize the leakage current in the pixel thin film transistor of display unit 21. In other words, the pixel thin film transistor requires a low OFF current.

When the gate is to be turned off, it is necessary to apply a negative voltage to the gate electrode since the pixel thin film transistor must be completely turned off. Since the pixel thin film transistor must have a positive voltage and a negative voltage applied to the gate when the transistor is to be turned on and off, respectively, a high AC stress resistance is required in addition to the requirement of a low OFF current in the pixel thin film transistor.

The region corresponding to the CMOS circuit in scanning line driving circuit 28 and data line driving circuitry 30 of the image display device does not have a negative voltage applied to the gate of the thin film transistor. Therefore, a high AC stress resistance is not particularly required at the thin film transistor employed in such circuitry.

In the image display device of the present embodiment, a thin film transistor of a GOLD structure described, for example, in the first embodiment is employed as the pixel thin film transistor. In circuitry corresponding to the CMOS circuit where high AC stress resistance is not required, a thin film transistor of a conventional LDD structure is employed.

The thin film transistor of a GOLD structure described in the first embodiment and the like has an occupying area larger than that of a thin film transistor of a conventional LDD structure. By appropriate arrangement of a thin film transistor of a GOLD structure and a thin film transistor of an LDD structure, increase of the occupying area of circuitry corresponding to thin film transistors in the liquid crystal display device can be suppressed.

Comparison of the occupying area between a thin film transistor of a GOLD structure and a thin film transistor of an LDD structure is specifically set forth hereinafter. The thin film transistor of a GOLD structure of interest has the following parameters: gate width 10 μm; length of GOLD region in direction of channel length 1 μm; and length of LDD region in direction of channel length 0.5 μm. The thin film transistor of an LDD structure of interest has the following parameters: gate width 10 μm; and length of LDD region in direction of channel length 0.5 μm. The channel lengths of respective gates are set to 1-5 μm.

FIG. 77 is a graph representing the dependency of the occupying area ratio of the thin film transistor of a GOLD structure according to the present invention to a thin film transistor of a conventional LDD structure on the gate length. It is appreciated from FIG. 77 that the occupying area of the thin film transistor of an LDD structure is apt to become smaller than the occupying area of a thin film transistor of a GOLD structure as the gate length becomes shorter.

Thus, by employing a thin film transistor of a GOLD structure for a thin film transistor where a low OFF current and high AC stress resistance are required such as a pixel thin film transistor, and employing a thin film transistor of a conventional LDD structure at circuitry where the requirement of AC stress resistance is not as high as that for a pixel thin film transistor, increase of the area occupied by circuitry in the image display device can be suppressed to the minimum level. The effect of suppressing increase in the occupying area becomes greater as the gate length becomes shorter.

The present invention is not limited to the above-described case in which a thin film transistor of a GOLD structure has one gate electrode, as described in the first embodiment, for the pixel thin film transistor. A thin film transistor of a GOLD structure having two gate electrodes shown in, for example, FIGS. 58 and 59, can be employed as the thin film transistor of a GOLD structure. Particularly, the OFF current can be further reduced by the provision of two gate electrodes, more suitable for a pixel thin film transistor.

### Eighteenth Embodiment

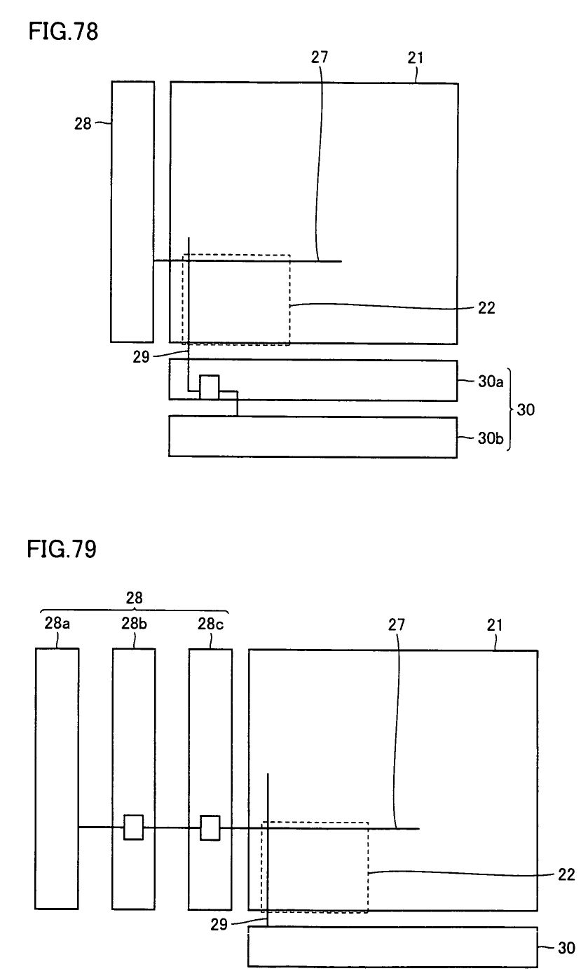

Another example of an image display device employing a thin film transistor of a GOLD structure will be described in the present embodiment. Data line driving circuit unit 30 of the above-described image display device is formed of an analog switch circuit unit 30a and a logic circuit unit 30b, as shown in FIG. 78.

At analog switch circuit unit 30a, the timing of transmitting a data signal onto data line 29 is controlled. When the gate of the thin film transistor functioning as a switching element in analog switch circuit unit 30a is turned on, a signal is applied onto data line 29, and the data signal is written into pixel 22 selected by scanning line 27.

Then, the thin film transistor in analog switch circuit unit 30a is turned off. It is to be noted that an ON signal is applied to scanning line 27 until the signal is written into all pixels 22 connected to the scanning line. Therefore, the signal applied to data line 29 and pixel 22 must be retained during the selection of scanning line 27. Thus, a low OFF current is required for the thin film transistor functioning as a switching element.

It is to be also noted that a negative voltage must be applied to the gate electrode since the thin film transistor must be completely turned off when the gate is turned off. Thus, a positive voltage and a negative voltage are applied to the gate at respective cases when the thin film transistor is turned ON and OFF, respectively, at switching circuit unit 30a. This means that a high AC stress resistance is required in addition to the requirement of a low OFF current in the thin film transistor.

In the image display device of the present embodiment, a thin film transistor of a GOLD structure as described in the first embodiment is employed as the thin film transistor functioning as a switching element in analog switching circuit unit 30a constituting data line driving circuit unit 30. In logic circuit unit 30b constituting data line driving circuit unit 30 where a high AC stress resistance is not required, a thin film transistor of a convention LDD structure is employed as the thin film transistor.

By employing a thin film transistor of a GOLD structure having a low OFF current and high AC stress resistance at analog switching circuit unit 30a, degradation of the image can be suppressed. Also, by applying a thin film transistor of a conventional LDD structure at logic circuit unit 30b, increase of the occupying area due to application of a thin film transistor of a GOLD structure can be suppressed.

As the thin film transistor at the switching circuit unit, any of the p type and n type thin film transistor can be applied.

### Nineteenth Embodiment

A further example of an image display device employing a thin film transistor of a GOLD structure will be described in the present embodiment. Scanning line driving circuit unit 28 in the above-described image display device is formed of a logic circuit unit 28a, a boosting circuit unit 28b, and an output circuit unit 28c.

A gate select signal is output from logic circuit unit 28a. Since the gate select signal from logic circuit unit 28a has a low voltage level, the signal voltage is boosted at boosting circuit unit 28b. Therefore, a high source-drain breakdown voltage is required at the thin film transistor in boosting circuit unit 28b.

The boosted signal (H, L) is further amplified at output circuit unit 28c to be provided to scanning line 27. Therefore, a high source-drain breakdown voltage is required also for the thin film transistor in output circuit unit 28c.

The image display device of the present embodiment employs the thin film transistor of a GOLD structure described in, for example, the first embodiment, as the thin film transistor in boosting circuit unit 28b and output circuit unit 28c constituting scanning line driving circuit unit 28. At circuitry where a high AC stress resistance is not required such as logic circuit unit 28a constituting scanning line driving circuit unit 28, a thin film transistor of a conventional LDD structure, for example, is employed as the thin film transistor.

By employing a thin film transistor of a GOLD structure having high source-drain breakdown voltage at boosting circuit unit 28b and output circuit unit 28c, high drivability can be ensured. Furthermore, by employing a thin film transistor of a conventional LDD structure at the logic circuit unit and the like, increase in the occupying area due to application of a thin film transistor of a GOLD structure can be suppressed.

### Twentieth Embodiment

The previous eighteenth embodiment is directed to an image display device employing a thin film transistor of a GOLD structure for the thin film transistor in the analog switching circuit unit of data line driving circuit unit 30. The previous nineteenth embodiment is directed to an image display device employing a thin film transistor of a GOLD structure as the thin film transistors of the boosting circuit unit and output circuit unit of scanning line driving circuit unit 28.

The present twentieth embodiment is directed to an image display device employing a thin film transistor of an LDD structure as the pixel thin film transistor of the pixel region, based on the application of a thin film transistor of a GOLD structure as the thin film transistor in the predetermined circuit units set forth above.

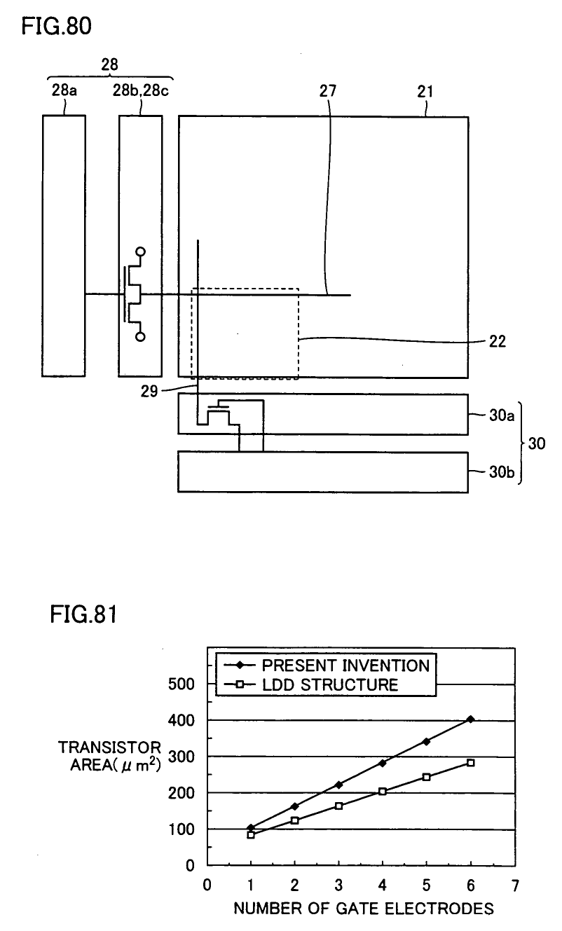

Referring to FIG. 80, the image display device employs a thin film transistor of a GOLD structure for the thin film transistor functioning as a switching element in analog switch circuit unit 30a of data line driving circuit unit 30. Furthermore, a thin film transistor of a GOLD structure is employed as the thin film transistors of boosting circuit unit 28b and output circuit unit 28c of scanning line driving circuit unit 28.

A thin film transistor of an LDD structure is employed as the pixel thin film transistor of display unit 21. Particularly, a thin film transistor having two gate electrodes, for example, is employed as such a thin film transistor of an LDD structure.

At display unit 21, the thin film transistor must have a low OFF current to retain the signal written in the pixel capacitance and the storage capacitance. Additionally, the opening rate of the region through which light can pass through must be set as high as possible to improve the light transmittance. Although increasing the number of gate electrodes for the thin film transistor is effective for the purpose of reducing the OFF current, increase of the gate electrodes will lead to a larger occupying area by the thin film transistor.

FIG. 81 is a graph representing the dependency of the occupying area of the thin film transistor of a GOLD structure of the present invention to the thin film transistor of a conventional LDD structure on the number of gate electrodes. It is appreciated from FIG. 81 that a thin film transistor of a GOLD structure having two gate electrodes, for example, occupies an area substantially equal to that of a thin film transistor of a conventional LDD structure having three gate electrodes.

Therefore, by employing a thin film transistor of an LDD structure as the pixel thin film transistor in the limited area of the pixel region in the above-described image display device, more gate electrodes can be provided to contribute to reduction in the OFF current.

By appropriately arranging a thin film transistor of a GOLD structure and a thin film transistor of an LDD structure in conformance with the specification required at each circuit unit in the liquid crystal display device of the eighteenth to twentieth embodiments, increase of the occupying area of circuitry can be suppressed to the minimum while exploiting the maximum performance of the liquid crystal display device.

Respective embodiments of a thin film transistor set forth above are described based on a planar type thin film transistor having a gate electrode formed with the gate insulation film therebetween on a semiconductor layer where a source region, a drain region, and the like are formed.

A thin film transistor of a GOLD structure of the present invention is not limited to such a planar type thin film transistor. A reverse stagger type thin film transistor having a semiconductor layer that is to function as a source region and a drain region and the like formed on a gate electrode with a gate insulation film therebetween may be employed. In such a thin film transistor of a reverse stagger structure, the junction between respective ones of GOLD region and LDD region is located substantially on the same plane as one side of the gate electrode, whereas the junction between respective other GOLD region and LDD region is located substantially on the same plane as the other side of the gate electrode.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising a semiconductor element having a semiconductor layer, an insulation film, and an electrode formed on a predetermined substrate, wherein said semiconductor element comprises a first element including
a first impurity region formed at said semiconductor layer,
a second impurity region formed at said semiconductor layer with a distance from said first impurity region,
a channel region functioning as a channel having a predetermined channel length, formed at a region of said semiconductor layer between said first impurity region and said second impurity region with respective distances from said first impurity region and said second impurity region,
a third impurity region formed in contact with said channel region at a region of said semiconductor layer between said first impurity region and said channel region,
a fourth impurity region formed in contact with said channel region at a region of said semiconductor layer between said second impurity region and said channel region,
a fifth impurity region formed at a region of said semiconductor layer between said first impurity region and said third impurity region, and
a sixth impurity region formed at a region of said semiconductor layer between said second impurity region and said fourth impurity region,
wherein, in said first element,
said electrode has one side and another side opposite to each other,
a junction between said third impurity region and said fifth impurity region is located substantially on a same plane as said one side, and a junction between said fourth impurity region and said sixth impurity region is located substantially on a same plane as said another side,
said electrode is formed overlapping with and facing entirely each of said channel region, said third impurity region, and said fourth impurity region,
said insulation film is formed between said semiconductor layer and said electrode so as to come into contact with each of said semiconductor layer and said electrode,
an impurity concentration of each of said third to sixth impurity regions is set lower than the impurity concentration of each of said first impurity region and said second impurity region, and higher than the impurity concentration of said channel region, and
the impurity concentration of said third and fourth impurity regions is set different from the impurity concentration of said fifth and sixth impurity regions.

2. The semiconductor device according to claim 1, wherein the impurity concentration of said third and fourth impurity regions is set lower than the impurity concentration of said fifth and sixth impurity regions.

3. The semiconductor device according to claim 2, wherein the impurity concentration of said third and fourth impurity regions is at least 1×10¹⁷ atom/cm³ and not more than 1×10¹⁹ atom/cm³.

4. The semiconductor device according to claim 2, wherein the impurity concentration of said fifth and sixth impurity regions is not more than 5×10¹⁹ atom/cm³.

5. The semiconductor device according to claim 2, wherein a length of said third impurity region and said fourth impurity region in a direction of the channel length is at least 0.5 μm and not more than 2 μm.

6. The semiconductor device according to claim 2, wherein a length of said fifth impurity region and said sixth impurity region in a direction of the channel length is at least 0.5 μm and not more than 1.5 μm.

7. The semiconductor device according to claim 2, wherein a difference between a length of said fifth impurity region in a direction of the channel length and a length of said sixth impurity region in a direction of the channel length is not more than 0.3 μm.

8. The semiconductor device according to claim 1, wherein an impurity concentration of said third and fourth impurity regions is set higher than the impurity concentration of said fifth and sixth impurity regions.

9. The semiconductor device according to claim 8, wherein the impurity concentration of said third and fourth impurity regions is at least 1×10¹⁷ atom/cm³ and not more than 1×10¹⁹ atom/cm³.

10. The semiconductor device according to claim 8, wherein a length of said third impurity region and said fourth impurity region in a direction of the channel length is at least 0.5 μm and not more than 2 μm.

11. The semiconductor device according to claim 8, wherein a length of said fifth impurity region and said sixth impurity region in a direction of the channel length is at least 0.5 μm, and not more than 1.5 μm.

12. The semiconductor device according to claim 8, wherein a difference between a length of said fifth impurity region in a direction of the channel length and a length of said sixth impurity region in a direction of the channel length is not more than 0.3 μm.

13. The semiconductor device according to claim 1, wherein a plurality of
said semiconductor elements are formed,
said semiconductor element comprising a second element including
a seventh impurity region formed at said semiconductor layer,
an eighth impurity region formed at said semiconductor layer with a distance from said seventh impurity region,
a channel region functioning as a channel having a predetermined channel length, formed at a portion of said semiconductor layer between said seventh impurity region and said eighth impurity region with respective distances from said seventh impurity region and said eighth impurity region,
a ninth impurity region formed in contact with said channel region at a region of said semiconductor layer between said seventh impurity region and said channel region, and
a tenth impurity region formed in contact with said channel region at a region of said semiconductor layer between said eighth impurity region and said channel region,
wherein, in said second element,
said electrode has one side and another side opposite to each other,
a junction between said channel region and said ninth impurity region is located substantially on a same plane as said one side, and a junction between said channel region and said tenth impurity region is located substantially on a same plane as said another side,
said electrode is formed overlapping with and facing said channel region entirely,
said insulation film is formed between said semiconductor layer and said electrode so as to come into contact with each of said semiconductor layer and said electrode, and
an impurity concentration of each of said ninth impurity region and said tenth impurity region is set lower than the impurity concentration of each of said seventh impurity region and said eighth impurity region, and higher than the impurity concentration of said channel region.

14. The semiconductor device according to claim 1, wherein said gate electrode is formed of a single layer.

15. An image display device comprising an image display circuit unit to display an image,
said image display circuit unit including a semiconductor element having a semiconductor layer, an insulation film, and an electrode formed on a predetermined substrate, wherein
said semiconductor element comprises a first element and a second element,
said first element including
a first impurity region formed at said semiconductor layer,
a second impurity region formed at said semiconductor layer with a distance from said first impurity region,
a channel region functioning as a channel having a predetermined channel length, formed at a region of said semiconductor layer between said first impurity region and said second impurity region with respective distances from said first impurity region and said second impurity region,
a third impurity region formed in contact with said channel region at a region of said semiconductor layer between said first impurity region and said channel region,
a fourth impurity region formed in contact with said channel region at a region of said semiconductor layer between said second impurity region and said channel region,
a fifth impurity region formed at a region of said semiconductor layer between said first impurity region and said third impurity region, and
a sixth impurity region formed at a region of said semiconductor layer between said second impurity region and said fourth impurity region,
said second element including
a seventh impurity region formed at said semiconductor layer,
an eighth impurity region formed at said semiconductor layer with a distance from said seventh impurity region,
a channel region functioning as a channel having a predetermined channel length, formed at a portion of said semiconductor layer between said seventh impurity region and said eighth impurity region with respective distances from said seventh impurity region and said eighth impurity region,
a ninth impurity region formed in contact with said channel region at a region of said semiconductor layer between said seventh impurity region and said channel region, and
a tenth impurity region formed in contact with said channel region at a region of said semiconductor layer between said eighth impurity region and said channel region
wherein, in said first element,
said electrode has one side and another side opposite to each other,
a junction between said third impurity region and said fifth impurity region is located substantially on a same plane as said one side, and a junction between said fourth impurity region and said sixth impurity region is located substantially on a same plane as said another side,
said electrode is formed overlapping with and facing entirely each of said channel region, said third impurity region, and said fourth impurity region,
said insulation film is formed between said semiconductor layer and said electrode so as to come into contact with each of said semiconductor layer and said electrode,
an impurity concentration of each of said third to sixth impurity regions is set lower than the impurity concentration of each of said first impurity region and said second impurity region, and higher than that concentration of said channel region, and
the impurity concentration of said third and fourth impurity regions is set different from the impurity concentration of said fifth and sixth impurity regions,
wherein, in said second element,
said electrode has one side and another side opposite to each other,
a junction between said channel region and said ninth impurity region is located substantially on a same plane as said one side, and a junction between said channel region and said tenth impurity region is located substantially on a same plane as said another side,
said electrode is formed overlapping with and facing said channel region entirely,
said insulation film is formed between said semiconductor layer and said electrode so as to come into contact with each of said semiconductor layer and said electrode, and
an impurity concentration of each of said ninth impurity region and said tenth impurity region is set lower than the impurity concentration of each of said seventh impurity region and said eighth impurity region, and higher than the impurity concentration of said channel region.

16. The image display device comprising an image display circuit unit according to claim 15, said image display circuit unit comprising
a pixel unit formed of a plurality of pixels for displaying an image, and
a driving circuit unit to operate said pixel unit,
wherein said first element is employed at one of said pixel unit and said driving circuit unit.

17. The image display device comprising an image display circuit unit according to claim 16, wherein
said first element is employed at each of said plurality of pixels in said pixel unit, and
said first element includes a plurality of said electrodes.

18. The image display device comprising an image display circuit unit according to claim 16, wherein said driving circuit unit comprises
a scanning line driving circuit unit including a boosting circuit unit connected to said pixel unit to boost and transmit a voltage of an image signal to respective said pixel in said pixel unit, and
a data line driving circuit unit including a switching circuit unit connected to said pixel unit to transmit a scanning signal to respective said pixel in said pixel unit,
wherein said first element is employed in at least one of said switching circuit unit and said boosting circuit unit.

19. The image display device comprising an image display circuit unit according to claim 18, wherein said driving circuit unit comprises a predetermined circuit unit in which said second element is employed.

20. The image display device comprising an image display circuit unit according to claim 16, wherein said second element is employed at said pixel unit.
